(19) United States
(12) Patent Application Publication
(10) Pub. No.: US 2014/0299359 A1
(43) Pub. Date: Oct. 9, 2014

(54) STRUCTURES WITH SURFACE-EMBEDDED ADDITIVES AND RELATED MANUFACTURING METHODS

(71) Applicant: Innova Dynamics, Inc., San Francisco, CA (US)

(72) Inventors: Alexander Chow Mittal, Berkeley, CA (US); Arjun Daniel Srinivas, San Francisco, CA (US); Matthew R. Robinson, San Francisco, CA (US); Michael Eugene Young, Emeryville, CA (US)

(21) Appl. No.: 14/247,033

(22) Filed: Apr. 7, 2014

Related U.S. Application Data
(63) Continuation of application No. 13/035,888, filed on Feb. 25, 2011, now abandoned.
Application No. 13/035,888 is a continuation-in-part of application No. 13/059,963, filed on May 10, 2011.
(60) Provisional application No. 61/189,540, filed on Aug. 21, 2008.
(60) Provisional application No. 61/203,661, filed on Dec. 26, 2008.
(60) Provisional application No. 61/409,116, filed on Nov. 2, 2010.
(60) Provisional application No. 61/308,894, filed on Feb. 27, 2010.
(60) Provisional application No. 61/311,396, filed on Mar. 8, 2010.
(60) Provisional application No. 61/311,395, filed on Mar. 8, 2010.
(60) Provisional application No. 61/408,773, filed on Nov. 1, 2010.

(51) Int. Cl. H05K 1/09; B05D 3/00; H05K 1/02; B05D 1/00

(52) U.S. Cl. CPC H05K 1/097; B05D 1/005; B05D 3/007; H05K 1/0271
USPC 174/251; 427/108

(57) ABSTRACT

Electrically conductive or semiconducting additives are embedded into surfaces of host materials for use in a variety of applications and devices. Resulting surface-embedded structures exhibit improved performance, as well as cost benefits arising from their compositions and manufacturing processes.

### CROSS REFERENCE TO RELATED APPLICATIONS

This application is a continuation of U.S. application Ser. No. 13/035,888, filed on Feb. 25, 2011, which is a continuation-in-part of U.S. application Ser. No. 13/059,963, filed on Feb. 18, 2011, which is the National Stage of International Application No. PCT/US2009/054655, filed on Aug. 21, 2009, which claims the benefit of U.S. Provisional Application No. 61/189,540, filed on Aug. 21, 2008, and U.S. Provisional Application No. 61/203,661, filed on Dec. 26, 2008, the disclosures of which are incorporated herein by reference in their entireties.

U.S. application Ser. No. 13/035,888 also claims the benefit of U.S. Provisional Application No. 61/308,894, filed on Feb. 27, 2010, U.S. Provisional Application No. 61/311,395, filed on Mar. 8, 2010, U.S. Provisional Application No. 61/311,396, filed on Mar. 8, 2010, U.S. Provisional Application No. 61/408,773, filed on Nov. 1, 2010, and U.S. Provisional Application No. 61/409,116, filed on Nov. 2, 2010, the disclosures of which are incorporated herein by reference in their entireties.

### FIELD OF THE INVENTION

The invention relates generally to structures with embedded additives. More particularly, the invention relates to structures with surface-embedded additives to impart functionality such as electrical conductivity.

### BACKGROUND

A transparent conductive electrode (“TCE”) permits the transmission of light while providing a conductive path for an electric current to flow through a device including the TCE. Traditionally, a TCE is formed of a coating of a doped metal oxide, such as indium tin oxide (“ITO”), which is disposed on top of a glass substrate. ITO is the most widely used material in conventional TCEs, as it strikes a balance between characteristics of solar flux-weighted transmittance Tₛₒₗₐᵣ and sheet resistance R, reaching performance levels of R≦10 Ω/sq at a solar flux-weighted transmittance of Tₛₒₗₐᵣ≧85%.

ITO coatings, however, suffer from a number of disadvantages. In particular, ITO coatings are typically manufactured via sputtering and annealing at energy-intensive high temperatures and vacuum environments, and etchants used during manufacturing can be corrosive and environmentally hazardous. In addition, the resulting ITO coatings can be brittle or subject to cracking, and also can be sensitive to acids and basis. Moreover, indium is an extremely scarce material, and its price has risen over a hundredfold the past 10 years or so. On top of the traditional requirements of high transparency and high conductivity, the future calls for devices and their components, including TCEs, to be robust, lightweight, and flexible—characteristics that are difficult to achieve using conventional ITO coatings. Similarly, for commercial purposes, driving down manufacturing costs is important, so TCEs should be producible at or near ambient temperatures and pressures with low curing time, using a highly-scalable and efficient manufacturing process.

It is against this background that a need arose to develop the surface-embedded structures and related manufacturing methods described herein.

### SUMMARY

Embodiments of the invention relate to electrically conductive or semiconducting additives that are embedded into embedding surfaces of host materials for use in a variety of applications and devices, including robust opaque conductive electrodes, TCEs (e.g, used in solar cells, displays, and lighting devices), touch panels, smart windows, electronic-paper, electromagnetic interference/radio frequency shields, electromagnetic pulse protection devices, anti-static shields, anti-dust shields, metamaterials, photonic devices, plasmonic devices, antennas, transistors (e.g., p-n junction devices, thin film transistors, and field effect transistors), diodes, light-emitting diodes, organic light-emitting diodes (“OLEDs”), sensors, actuators, construction materials, building materials, electronics casings, consumer devices, memory storage devices, energy storage devices (e.g., batteries, capacitors, and ultra-capacitors), solar energy generation devices, piezoelectric energy generation devices, radio frequency identification devices, thermal conductors/cooling/heating devices, interconnects, hybrid devices, frequency-selective surfaces and devices, and so forth.

Embodiments of surface-embedded structures exhibit improved performance (e.g., higher electrical and thermal conductivity, higher light transmittance, and higher electromagnetic field shielding or absorption), as well as cost benefits arising from their composition and manufacturing process. The structures can be manufactured by, for example, a surface embedding process in which additives are physically embedded into a host material, while preserving desired characteristics of the host material (e.g., transparency) and imparting additional desired characteristics to the resulting surface-embedded structures (e.g., electrical conductivity).

Other aspects and embodiments of the invention are also contemplated. The foregoing summary and the following detailed description are not meant to restrict the invention to any particular embodiment but are merely meant to describe some embodiments of the invention.

### BRIEF DESCRIPTION OF THE DRAWINGS

For a better understanding of the nature and objects of some embodiments of the invention, reference should be made to the following detailed description taken in conjunction with the accompanying drawings.

FIG. 1A illustrates a structure in which additives are mixed throughout a bulk of a substrate.

FIG. 1B illustrates a structure in which additives are mixed throughout a coating that is on top of a substrate.

FIG. 1C illustrates a structure in which additives are superficially or surface deposited on top of a substrate.

FIG. 1D through FIG. 1H illustrate various surface-embedded structures implemented in accordance with embodiments of the invention.

FIG. 2A through FIG. 2G illustrate additional surface-embedded structures implemented in accordance with embodiments of the invention.

FIG. 3 is a logarithmic plot of resistance versus loading level of additives, according to an embodiment of the invention.

FIG. 4A through FIG. 4C illustrate manufacturing methods to form surface-embedded structures, according to embodiments of the invention.

FIG. 5A illustrates a LCD according to an embodiment of the invention.

FIG. 5B illustrates a color filter for use in an LCD according to an embodiment of the invention.

FIG. 6 illustrates thin-film solar cells according to an embodiment of the invention.

FIG. 7 illustrates a projected capacitive touch screen device according to an embodiment of the invention.

FIG. 8 illustrates an OLED lighting device according to an embodiment of the invention.

FIG. 9 illustrates an e-paper according to an embodiment of the invention.

FIG. 10 illustrates a smart window according to an embodiment of the invention.

FIG. 11 illustrates a tradeoff curve of transmittance and corresponding sheet resistance (at constant DC-to-optical conductivity ratio) of silver nanowire networks surface-embedded into polycarbonate films and acrylic, according to an embodiment of the invention.

FIG. 12 is a table of transparency and sheet resistance data collected on samples manufactured via a two-step deposition and embedding method, comparing data directly after deposition and after surface-embedding, according to an embodiment of the invention.

FIG. 13 is a table summarizing typical, average sheet resistance and transparency data for different methods of fabricating TCEs with surface-embedded additives, according to an embodiment of the invention.

FIGS. 14, 14(a), 14(b), 14(c), 14(d), 14(e), 14(f), 14(g), 14(h), 14(i), 14(j), 14(k), and 14(l) depict various configurations of additive concentrations relative to an embedding surface of a host material, according to an embodiment of the invention.

### DETAILED DESCRIPTION

### Definitions

The following definitions apply to some of the elements described with regard to some embodiments of the invention. These definitions may likewise be expanded upon herein.

As used herein, the singular terms “a,” “an,” and “the” include plural referents unless the context clearly dictates otherwise. Thus, for example, reference to an object can include multiple objects unless the context clearly dictates otherwise.

As used herein, the term “set” refers to a collection of one or more objects. Thus, for example, a set of objects can include a single object or multiple objects. Objects of a set can also be referred to as members of the set. Objects of a set can be the same or different. In some instances, objects of a set can share one or more common characteristics.

As used herein, the term “adjacent” refers to being near or adjoining. Adjacent objects can be spaced apart from one another or can be in actual or direct contact with one another. In some instances, adjacent objects can be connected to one another or can be formed integrally with one another.

As used herein, the terms “connect,” “connected,” and “connection” refer to an operational coupling or linking. Connected objects can be directly coupled to one another or can be indirectly coupled to one another, such as via another set of objects.

As used herein, the terms “substantially” and “substantial” refer to a considerable degree or extent. When used in conjunction with an event or circumstance, the terms can refer to instances in which the event or circumstance occurs precisely as well as instances in which the event or circumstance occurs to a close approximation, such as accounting for typical tolerance levels of the manufacturing methods described herein.

As used herein, the terms “optional” and “optionally” mean that the subsequently described event or circumstance may or may not occur and that the description includes instances where the event or circumstance occurs and instances in which it does not.

As used herein, relative terms, such as “inner,” “interior,” “outer,” “exterior,” “top,” “bottom,” “upper,” “upwardly,” “lower,” “downwardly,” “vertical,” “vertically,” “lateral,” “laterally,” “above,” and “below,” refer to an orientation of a set of objects with respect to one another, such as in accordance with the drawings, but do not require a particular orientation of those objects during manufacturing or use.

As used herein, the term “sub-nanometer range” or “sub-nm range” refers to a range of dimensions less than about 1 nm, such as from about 0.1 nm to about 1 nm.

As used herein, the term “nanometer range” or “nm range” refers to a range of dimensions from about 1 nm to about 1 micrometer (“μm”). The nm range includes the “lower nm range,” which refers to a range of dimensions from about 1 nm to about 10 nm, the “middle nm range,” which refers to a range of dimensions from about 10 nm to about 100 nm, and the “upper nm range,” which refers to a range of dimensions from about 100 nm to about 1 μm.

As used herein, the term “micrometer range” or “μm range” refers to a range of dimensions from about 1 μm to about 1 mm. The μm range includes the “lower μm range,” which refers to a range of dimensions from about 1 μm to about 10 μm, the “middle μm range,” which refers to a range of dimensions from about 10 μm to about 100 μm, and the “upper μm range,” which refers to a range of dimensions from about 100 μm to about 1 mm.

As used herein, the term “aspect ratio” refers to a ratio of a largest dimension or extent of an object and an average of remaining dimensions or extents of the object, where the remaining dimensions are orthogonal with respect to one another and with respect to the largest dimension. In some instances, remaining dimensions of an object can be substantially the same, and an average of the remaining dimensions can substantially correspond to either of the remaining dimensions. For example, an aspect ratio of a cylinder refers to a ratio of a length of the cylinder and a cross-sectional diameter of the cylinder. As another example, an aspect ratio of a spheroid refers to a ratio of a major axis of the spheroid and a minor axis of the spheroid.

As used herein, the term “nano-sized additive” refers to an additive that has at least one dimension in the nm range. A nano-sized additive can have any of a wide variety of shapes, and can be formed of a wide variety of materials. Examples of nano-sized additives include nanowires, nanotubes, and nanoparticles.

As used herein, the term “nanowire” refers to an elongated, nano-sized additive that is substantially solid. Typically, a nanowire has a lateral dimension (e.g., a cross-sectional dimension in the form of a width, a diameter, or a width or diameter that represents an average across orthogonal directions) in the nm range, a longitudinal dimension (e.g., a length) in the μm range, and an aspect ratio that is about 3 or greater.

As used herein, the term “nanotube” refers to an elongated, hollow, nano-sized additive. Typically, a nanotube has a lateral dimension (e.g., a cross-sectional dimension in the form of a width, an outer diameter, or a width or outer diameter that represents an average across orthogonal directions) in the nm range, a longitudinal dimension (e.g., a length) in the μm range, and an aspect ratio that is about 3 or greater.

As used herein, the term “nanoparticle” refers to a spheroidal, nano-sized additive. Typically, each dimension (e.g., a cross-sectional dimension in the form of a width, a diameter, or a width or diameter that represents an average across orthogonal directions) of a nanoparticle is in the nm range, and the nanoparticle has an aspect ratio that is less than about 3, such as about 1.

As used herein, the term “micron-sized additive” refers to an additive that has at least one dimension in the μm range. Typically, each dimension of a micron-sized additive is in the μm range or beyond the μm range. A micron-sized additive can have any of a wide variety of shapes, and can be formed of a wide variety of materials. Examples of micron-sized additives include microwires, microtubes, and microparticles.

As used herein, the term “microwire” refers to an elongated, micron-sized additive that is substantially solid. Typically, a microwire has a lateral dimension (e.g., a cross-sectional dimension in the form of a width, a diameter, or a width or diameter that represents an average across orthogonal directions) in the μm range and an aspect ratio that is about 3 or greater.

As used herein, the term “microtube” refers to an elongated, hollow, micron-sized additive. Typically, a microtube has a lateral dimension (e.g., a cross-sectional dimension in the form of a width, an outer diameter, or a width or outer diameter that represents an average across orthogonal directions) in the μm range and an aspect ratio that is about 3 or greater.

As used herein, the term “microparticle” refers to a spheroidal, micron-sized additive. Typically, each dimension (e.g., a cross-sectional dimension in the form of a width, a diameter, or a width or diameter that represents an average across orthogonal directions) of a microparticle is in the μm range, and the microparticle has an aspect ratio that is less than about 3, such as about 1.

### Structures with Surface-Embedded Additives

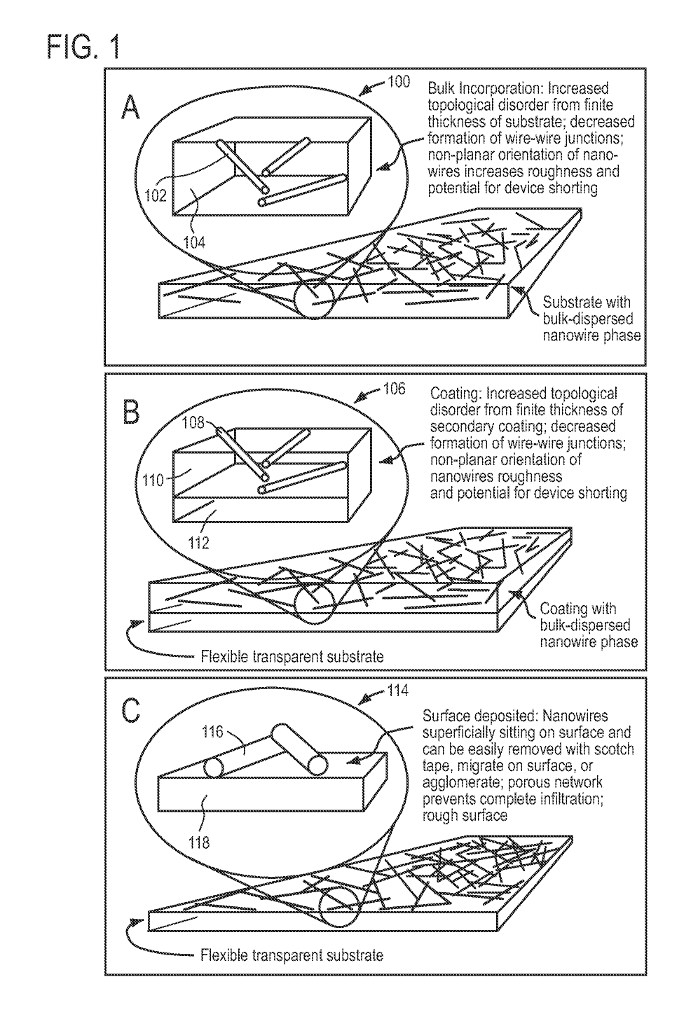

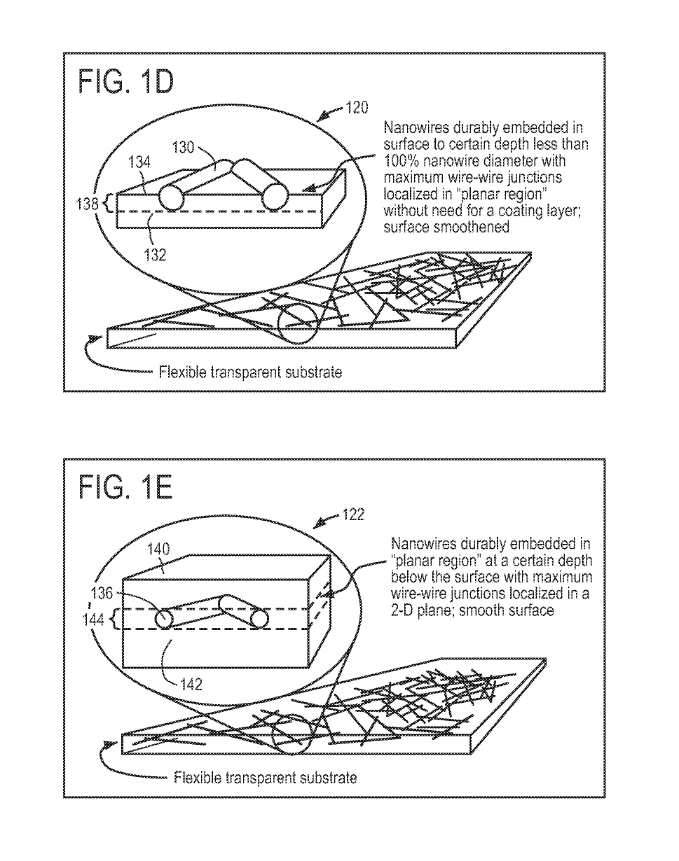

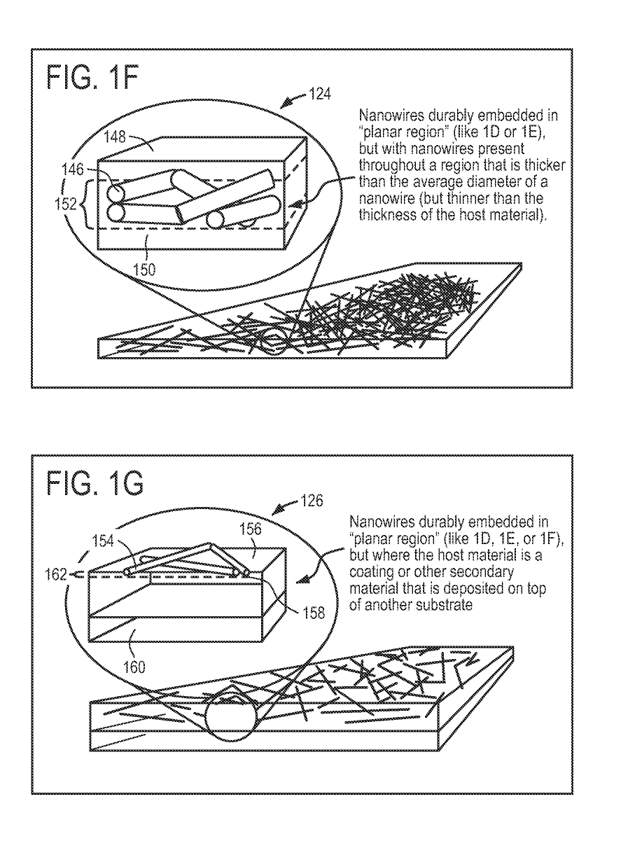

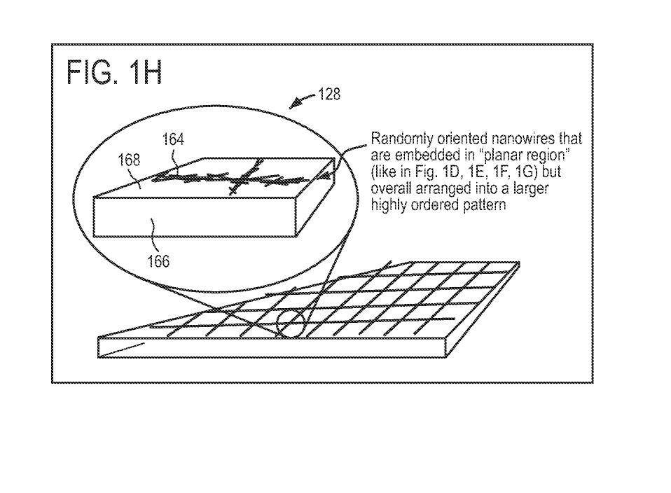

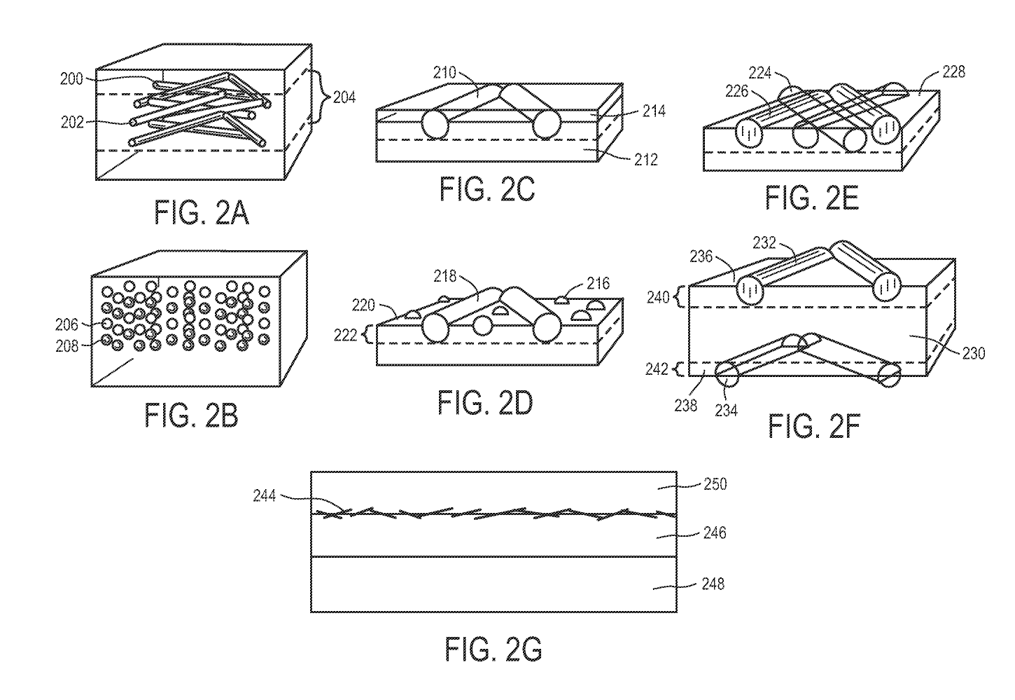

The surface-embedded structures described herein differ from other possible approaches that seek to attain electrical conductivity through incorporation of electrically conductive additives. Three other approaches are illustrated in FIG. 1A through FIG. 1C and are contrasted with improved surface-embedded structures illustrated and described with reference to FIG. 1D through FIG. 1H and FIG. 2A through FIG. 2G.

FIG. 1A depicts a structure 100 in which additives 102 are mixed throughout a bulk of a substrate 104. FIG. 1B depicts a structure 106 in which additives 108 are mixed throughout a coating 110, which (along with the additives 108) is disposed on top of a substrate 112. FIG. 1C depicts a structure 114 in which additives 116 are superficially or surface deposited on top of a substrate 118—such a configuration has poor adhesion of the surface-deposited additives 116 to the substrate 118.

In contrast, FIG. 1D through FIG. 1H depict various surface-embedded structures 120, 122, 124, 126, and 128 implemented in accordance with embodiments of the invention. FIG. 1D is a schematic of surface-embedded additives 130 that form a network that is partially exposed and partially buried into a top, embedding surface 134 of a host material 132, which corresponds to a substrate. As illustrated in FIG. 1D, the network of the additives 130 is localized adjacent to the embedding surface 134 and within an embedding region 138 of the host material 132, with a remainder of the host material 132 largely devoid of the additives 130. In the illustrated embodiment, the embedding region 138 is relatively thin (e.g., having a thickness less than or much less than an overall thickness of the host material 132, or having a thickness comparable to a characteristic dimension of the additives 130), and, therefore, can be referred to as “planar” or “planar-like.” Through proper selection of the host material 132, such as certain polymers or polymer-containing composite materials, the substrate can be transparent and flexible, as well as lightweight. However, other embodiments can be implemented in which the substrate need not be transparent or flexible as labeled. The surface-embedded structure 120 (as well as other surface-embedded structures described herein) can be much smoother than conventional structures. High smoothness (e.g., low roughness) can be desirable for TCEs used in, for example, solar cells and displays, because roughness can lead to penetration into adjacent device layers and other undesirable effects.

FIG. 1E is a schematic of surface-embedded additives 136 that form a network that is fully embedded into a top, embedding surface 140 of a host material 142, which corresponds to a substrate. As illustrated in FIG. 1E, the network of the additives 136 is localized adjacent to the embedding surface 140 and within an embedding region 144 of the host material 142, with a remainder of the host material 142 largely devoid of the additives 136. In the illustrated embodiment, the embedding region 144 is relatively thin (e.g., having a thickness less than or much less than an overall thickness of the host material 142, or having a thickness comparable to a characteristic dimension of the additives 136), and, therefore, can be referred to as “planar” or “planar-like.” In such manner, the network of the additives 136 can remain in a substantially planar configuration, despite being fully embedded underneath the embedding surface 140 by a certain relatively uniform distance. Through proper selection of the host material 142, such as certain polymers or polymer-containing composite materials, the substrate can be transparent and flexible, as well as lightweight. However, other embodiments can be implemented in which the substrate need not be transparent or flexible as labeled.

FIG. 1F is a schematic of surface-embedded additives 146 that form a network that is fully embedded into a top, embedding surface 148 of a host material 150, which corresponds to a substrate. As illustrated in FIG. 1F, the network of the additives 146 is localized adjacent to the embedding surface 148 and within an embedding region 152 of the host material 150, with a remainder of the host material 150 largely devoid of the additives 146. In the illustrated embodiment, a thickness of the embedding region 152 is greater than a characteristic dimension of the additives 146 (e.g., a cross-sectional diameter of an individual one of the additives 146 or an average cross-sectional diameter across the additives 146), but still less than (or much less) than an overall thickness of the host material 150. The additives 146 can be distributed or arranged within the embedding region 152 as multiple layers, with the additives 146 of a particular layer remaining in a substantially planar configuration, despite being fully embedded underneath the embedding surface 148. Note that, although not illustrated in FIG. 1F, another implementation would be similar to FIG. 1F, but with the network of the additives 146 partially exposed at the embedding surface 148 of the host material 150.

FIG. 1G is a schematic of surface-embedded additives 154 that form a network that is partially exposed and partially buried into a top, embedding surface 156 of a host material 158, which corresponds to a coating or other secondary material, such as a slurry or a paste, that is disposed on top of a substrate 160. As illustrated in FIG. 1G, the network of the additives 154 is localized adjacent to the embedding surface 156 and within an embedding region 162 of the host material 158, with a remainder of the host material 158 largely devoid of the additives 154. It is also contemplated that the additives 154 can be distributed throughout a larger volume fraction within the host material 158, such as in the case of a relatively thin coating having a thickness comparable to a characteristic dimension of the additives 154. In the illustrated embodiment, the embedding region 162 is relatively thin, and, therefore, can be referred to as “planar” or “planar-like.” Note that, although not illustrated in FIG. 1G, another implementation would be similar to FIG. 1G, buy with the network of additives 154 fully embedded below the embedding surface 156 of the host material 158.

FIG. 1H is a schematic of surface-embedded additives 164 that form a network that is localized across a host material 166 so as to form an ordered pattern. The network of the additives 164 can be partially embedded into a top, embedding surface 168 and localized within an embedding region 162 of the host material 166 (e.g., similar to FIG. 1D and FIG. 1G), fully embedded below the embedding surface 168 (e.g., similar to FIG. 1E and FIG. 1F), or a combination thereof, but the network is not located uniformly across the host material 166 but rather is patterned. Note that, although a grid pattern is illustrated in FIG. 1H, patterns, in general, can include aperiodic (or non-periodic, random) patterns as well as periodic patterns, such as diamond patterns, square patterns, rectangular patterns, triangular patterns, various polygonal patterns, wavy patterns, angular patterns, interconnect patterns (e.g., in the form circuitry in electronic devices, displays, solar panels, energy storage devices, such as batteries or ultra-capacitors), or any combination thereof. FIG. 1I illustrates that, although the formation of a patterns occur, a zoomed up view of a “line” section of the pattern reveals that the configuration of the individual “line” section includes surface-embedded additives similar to any, or a combination, of the configurations illustrated in FIG. 1D through FIG. 1G and FIG. 2 below. The additives 164 (as well as the additives illustrated in FIG. 1D through FIG. 1G and FIG. 2 below) desirably include metallic nanowires, such as silver (or Ag) nanowires, copper (or Cu) nanowires, or a combination thereof, with a longitudinal dimension that is, on average, shorter than a characteristic length of the pattern (e.g., a length of an individual “line” section), a longitudinal dimension that is, on average, longer than a characteristic width of the pattern (e.g., a width of an individual “line” section), or both. Other types of additives and other combinations of additives also can be used in place of, or in combination with, metallic nanowires, such as nanoparticles including metallic nanoparticles like silver nanoparticles. In some embodiments, the additives 164 can be sintered or otherwise fused to form solid lines, which can serve as interconnects or interconnection grids for use in devices such as touch screen devices and smart windows. Such embodiments provide a number of advantages over conventional approaches, including enhanced durability and allowing the omission of a coating or other binding material that can be prone to delamination and that can inhibit conductivity or increase resistance.

Other configurations of surface-embedded structures are illustrated in FIG. 2A through FIG. 2G. Certain aspects of the surface-embedded structures illustrated in FIG. 2A through FIG. 2G can be implemented in a similar fashion as illustrated and described above in FIG. 1D through FIG. 1H, and those aspects are not repeated below.

FIG. 2A is a schematic of surface-embedded additives that form a network, in which the network includes at least two different types of additives 200 and 202 in the form of different types of nanowires, different types of nanotubes, or a combination thereof. In general, the additives 200 and 202 can differ, for example, in terms of their dimensions, shapes, material composition, or a combination thereof. As illustrated in FIG. 2A, the additives 200 and 202 are localized within an embedding region 204 in a particular arrangement, such as in a layered arrangement. Each layer can primarily include a respective, different type of additive, although additives of different types also cross between layers. Such a layered arrangement of the additives 200 and 202 also can be described in terms of different embedding regions, with each different type of additive being localized within a respective embedding region. Although the additives 200 and 202 are illustrated as fully embedded, it is contemplated that at least some of the additives 200 and 202 can be partially embedded and surface-exposed. FIG. 2B is a schematic similar to FIG. 2A, but with at least two different types of additives 206 and 208 in the form of different types of nanoparticles. It is also contemplated that nanoparticles can be included in combination with either, or both, nanowires and nanotubes. It is further contemplated that other embodiments described herein in terms of a particular type of additive can be implemented with different types of additives. Although the additives 206 and 208 are illustrated as fully embedded, it is contemplated that at least some of the additives 206 and 208 can be partially embedded and surface-exposed.

FIG. 2C is a schematic of surface-embedded additives 210 that are partially embedded into a host material 212, which corresponds to a substrate, and where a coating 214 fills in at least one layer around the additives 210, either fully covering the additives 210 or leaving them partially exposed as illustrated in FIG. 2C. The coating 214 can have the same or a similar composition as the host material 212 (or other host materials described herein), or can have a different composition to provide additional or modified functionality, such as when implemented using an electrically conductive material or semiconductor (e.g., ITO, ZnO(i), ZnO:Al, ZnO:B, SnO₂:F, Cd₂SnO₄, CdS, ZnS, other doped metal oxide, an electrically conductive or semiconductive polymer, a fullerene-based coating, such as carbon nanotube-based coating, or another electrically conductive material that is transparent) to serve as a buffer layer to adjust a work function in the context of TCEs for solar cells or to provide a conductive path for the flow of an electric current, in place of, or in combination, with a conductive path provided by the surface-embedded additives 210. In the case of ITO, for example, the presence of the surface-embedded additives 210 can provide cost savings by allowing a reduced amount of ITO to be used and, therefore, a reduced thickness of the coating 214 (relative to the absence of the additives 210), such as a thickness less than about 100 nm, such as no greater than about 75 nm, no greater than about 50 nm, no greater than about 40 nm, no greater than about 30 nm, no greater than about 20 nm, no greater than about 10 nm, and down to about 5 nm or less. Additionally, the presence of the surface-embedded additives 210 can allow for solution deposition of ITO (instead of sputtering) with a low temperature cure. The resulting, relatively low conductivity ITO layer can still satisfy work function matching, while the additives 210 can mitigate the reduced conductivity exhibited by solution-deposited ITO without high temperature cure. It is contemplated that the additives 210 can be arranged in a pattern (e.g., a grid pattern or any other pattern such as noted above for FIG. 1H), and the coating 214 can be formed with a substantially matching pattern (e.g., a matching grid pattern or any other matching pattern such as noted above for FIG. 1H) so as to either fully cover the additives 210 or leaving them partially exposed.

FIG. 2D is a schematic similar to FIG. 1D, but with nanoparticles 216 surface-embedded in combination with nanowires 218 (or other high aspect ratio additives) and localized within a “planar” or “planar-like” embedding region 222. Although not shown, either, or both, of the nanoparticles 216 and the nanowires 218 can be fully below a top, embedding surface 220 (e.g., similar to the configuration illustrated in FIG. 1E or FIG. 1F).

FIG. 2E is a schematic similar to FIG. 1D, but with at least two different types of additives 224 and 226 in the form of different types of nanowire, different types of nanotubes, or a combination of nanowires and nanotubes. Although not shown, either, or both, of the different types of additives 224 and 226 can be fully below a top, embedding surface 228 (e.g., similar to the configuration illustrated in FIG. 1E or FIG. 1F).

FIG. 2F is a schematic of a host material 230, such as in the form of a film, and where the host material 230 is embedded with additives on either side of the host material 230. In particular, additives 232 are at least partially embedded into a top, embedding surface 236 of the host material 230 and localized adjacent to the top, embedding surface 236 and within an embedding region 240 of the host material 230, while additives 234 are at least partially embedded into a bottom, embedding surface 238 of the host material 230 and localized adjacent to the bottom, embedding surface 238 and within an embedding region 242 of the host material 230. It is contemplated that, for any particular side of the host material 230, the extent of embedding of additives in the host material 230 or the inclusion of different types of additives can be implemented in a similar fashion as described above and subsequently below. It is further contemplated that additives can be embedded into additional surfaces of the host material 230, such as any one or more of the lateral surfaces of the host material 230.

The surface-embedded structure illustrated in FIG. 2F can be useful, for example, for an energy storage device, where the host material 230 includes a solid polymer electrolyte material, and the additives 232 and 234 serve as a pair of electrodes or current collectors and include electrically conductive materials, such as carbon, a metal, a metal oxide, carbon black, graphene, or a combination thereof, in the form of nanoparticles, microparticles, nanowires, microwires, nanotube, microtubes, or other forms or a combination of such forms. The surface-embedded structure illustrated in FIG. 2F also can be useful, for example, for a touch screen device, where the additives 232 and 234 serve as a pair of electrodes, and a region of the host material 230 in between the additives 232 and 234 serve as a thin-film separator.

FIG. 2G is a schematic similar to FIG. 2C, but with surface-embedded additives 244 that are partially embedded into a host material 246, which corresponds to a coating disposed on top of a substrate 248, and where another coating 250 fills in at least one layer around the additives 244 and is electrically coupled to the additives 244, either leaving them partially exposed or fully covering the additives 244 as illustrated in FIG. 2G. By fully covering the additives 244, the resulting surface of the coating 250 is quite smooth (e.g., having a smoothness or a roughness substantially comparable to that of an inherent smoothness or roughness of the coating 250 in the absence of the additives 244). The coating 250 can have the same or a similar composition as the host material 246 (or other host materials described herein), or can have a different composition to provide additional or modified functionality, such as when implemented using an electrically conductive material or semiconductor (e.g., ITO, ZnO(i), ZnO:Al, ZnO:B, SnO₂:F, Cd₂SnO₄, CdS, ZnS, other doped metal oxide, an electrically conductive or semiconducting polymer, a fullerene-based coating, such as carbon nanotube-based coating, or another electrically conductive material that is transparent) to serve as a buffer layer to adjust a work function in the context of TCEs for solar cells or to provide a conductive path for the flow of an electric current, in place of, or in combination, with a conductive path provided by the surface-embedded additives 244. In the case of ITO, for example, the presence of the surface-embedded additives 244 can provide cost savings by allowing a reduced amount of ITO to be used and, therefore, a reduced thickness of the coating 250 (relative to the absence of the additives 244), such as a thickness less than about 100 nm, such as no greater than about 75 nm, no greater than about 50 nm, no greater than about 40 nm, no greater than about 30 nm, no greater than about 20 nm, no greater than about 10 nm, and down to about 5 nm or less. Additionally, the presence of the surface-embedded additives 244 can allow for solution deposition of ITO (instead of sputtering) with a low temperature cure. The resulting, relatively low conductivity ITO layer can still satisfy work function matching, while the additives 244 can mitigate the reduced conductivity exhibited by solution-deposited ITO without high temperature cure. It is contemplated that the additives 244 can be arranged in a pattern (e.g., a grid pattern or any other pattern such as noted above for FIG. 1H), and the coating 250 can be formed with a substantially matching pattern (e.g., a matching grid pattern or any other matching pattern such as noted above for FIG. 1H) so as to either fully cover the additives 244 or leaving them partially exposed.

One aspect of certain surface-embedded structures described herein is the provision of a vertical additive concentration gradient in a host material, namely such a gradient along a thickness direction of the host material. Bulk incorporation (e.g., as illustrated in FIG. 1A) aims to provide an uniform vertical additive concentration gradient throughout a host material, although agglomeration and other effects may prevent such uniform gradient to be achieved in practice. For a conventional coating implementation (e.g., as illustrated in FIG. 1B), a vertical additive concentration gradient can exist as between a coating and an underlying substrate; however, and similar to bulk incorporation, a conventional coating implementation aims to provide an uniform vertical additive concentration gradient throughout the coating. In contrast, the surface-embedded structures allow for variable, controllable vertical additive concentration gradient, in accordance with a localization of additives within an embedding region of the host material. For certain implementations, the extent of localization of additives within an embedding region is such that at least a majority (by weight, volume, or number density) of the additives are included within the embedding region, at least 60% (by weight, volume, or number density) of the additives are so included, at least 70% (by weight, volume, or number density) of the additives are so included, at least 80% (by weight, volume, or number density) of the additives are so included, or at least 90% (by weight, volume, or number density) of the additives are so included, or at least 95% (by weight, volume, or number density) of the additives are so included. For example, substantially all of the additives can be localized within the embedding region, such that a remainder of the host material is substantially devoid of the additives.

In general, additives can include an electrically conductive material, a semiconductor, or a combination thereof, which can be in the form of nano-sized additives, micron-sized additives, as well as additives sized in the sub-nm range. For example, at least one additive can have a cross-sectional dimension (or a population of additives can have an average cross-sectional dimension) in the range of about 0.1 nm to about 1 mm. In some embodiments, the cross-sectional dimension (or the average cross-sectional dimension) is in the range of about 1 nm to about 100 nm, about 1 nm to about 20 nm, about 20 nm to about 100 nm, about 1 nm to about 50 microns, about 100 nm to about 1 micron, about 1 nm to about 100 microns, or about 500 nm to about 50 microns. In some embodiments, substantially all additives have a cross-sectional dimension in the range of about 0.1 nm to about 1 mm or about 0.1 nm to about 100 microns.

Examples of electrically conductive materials include metals (e.g., silver, copper, and gold), metal alloys, carbon-based conductors (e.g., carbon nanotubes, graphene, and buckyballs), metal oxides that are optionally doped (e.g., ITO, ZnO(i), ZnO:Al, ZnO:B, SnO₂:F, Cd₂SnO₄, CdS, ZnS, and other doped metal oxide), electrically conductive polymers, and any combination thereof. Examples of semiconductor materials include semiconducting polymers, Group IVB elements (e.g., carbon (or C), silicon (or Si), and germanium (or Ge)), Group IVB-IVB binary alloys (e.g., silicon carbide (or SiC) and silicon germanium (or SiGe)), Group IIB-VIB binary alloys (e.g., cadmium selenide (or CdSe), cadmium sulfide (or CdS), cadmum telluride (or CdTe), zinc oxide (or ZnO), zinc selenide (or ZnSe), zinc telluride (or ZnTe), and zinc sulfide (or ZnS)), Group IIB-VIB ternary alloys (e.g., cadmium zinc telluride (or CdZnTe), mercury cadmium telluride (or HgCdTe), mercury zinc telluride (or HgZnTe), and mercury zinc selenide (or HgZnSe)), Group IIIB-VB binary alloys (e.g., aluminum antimonide (or AlSb), aluminum arsenide (or AlAs), aluminium nitride (or AlN), aluminium phosphide (or AlP), boron nitride (or BN), boron phosphide (or BP), boron arsenide (or BAs), gallium antimonide (or GaSb), gallium arsenide (or GaAs), gallium nitride (or GaN), gallium phosphide (or GaP), indium antimonide (or InSb), indium arsenide (or InAs), indium nitride (or InN), and indium phosphide (or InP)), Group IIIB-VB ternary alloys (e.g., aluminium gallium arsenide (or AlGaAs or AlₓGa₁₋ₓAs), indium gallium arsenide (or InGaAs or InₓGa₁₋ₓAs), indium gallium phosphide (or InGaP), aluminium indium arsenide (or AlInAs), aluminium indium antimonide (or AlInSb), gallium arsenide nitride (or GaAsN), gallium arsenide phosphide (or GaAsP), aluminium gallium nitride (or AlGaN), aluminium gallium phosphide (or AlGaP), indium gallium nitride (or InGaN), indium arsenide antimonide (or InAsSb), and indium gallium antimonide (or InGaSb)), Group IIIB-VB quaternary alloys (e.g., aluminium gallium indium phosphide (or AlGaInP), aluminium gallium arsenide phosphide (or AlGaAsP), indium gallium arsenide phosphide (or InGaAsP), aluminium indium arsenide phosphide (or AlInAsP), aluminium gallium arsenide nitride (or AlGaAsN), indium gallium arsenide nitride (or InGaAsN), indium aluminium arsenide nitride (or InAlAsN), and gallium arsenide antimonide nitride (or GaAsSbN)), and Group IIIB-VB quinary alloys (e.g., gallium indium nitride arsenide antimonide (or GaInNAsSb) and gallium indium arsenide antimonide phosphide (or GaInAsSbP)), Group IB-VIIB binary alloys (e.g., cupruous chloride (or CuCl)), Group IVB-VIB binary alloys (e.g., lead selenide (or PbSe), lead sulfide (or PbS), lead telluride (or PbTe), tin sulfide (or SnS), and tin telluride (or SnTe)), Group IVB-VIB ternary alloys (e.g., lead tin telluride (or PbSnTe), thallium tin telluride (or Tl₂SnTe₅), and thallium germanium telluride (or Tl₂GeTe₅)), Group VB-VIB binary alloys (e.g., bismith telluride (or Bi₂Te₃)), Group IIB-VB binary alloys (e.g., cadmium phosphide (or Cd₃P₂), cadmium arsenide (or Cd₃As₂), cadmium antimonide (or Cd₃Sb₂), zinc phosphide (or Zn₃P₂), zinc arsenide (or Zn₃As₂), and zinc antimonide (or Zn₃Sb₂)), and other binary, ternary, quaternary, or higher order alloys of Group IB (or Group 11) elements, Group IIB (or Group 12) elements, Group IIIB (or Group 13) elements, Group IVB (or Group 14) elements, Group VB (or Group 15) elements, Group VIB (or Group 16) elements, and Group VIIB (or Group 17) elements, such as copper indium gallium selenide (or CIGS), as well as any combination thereof.

Additives can include, for example, nanoparticles, nanowires, nanotubes (e.g., multi-walled nanotubes (“MWNTs”), single-walled nanotubes (“SWNTs”), double-walled nanotubes (“DWNTs”), graphitized or modified nanotubes), fullerenes, buckyballs, graphene, microparticles, microwires, microtubes, core-shell nanoparticles or microparticles, core-multishell nanoparticles or microparticles, core-shell nanowires, and other additives having shapes that are substantially tubular, cubic, spherical, or pyramidal, and characterized as amorphous, crystalline, tetragonal, hexagonal, trigonal, orthorhombic, monoclinic, or triclinic, or any combination thereof.

Example of core-shell particles and core-shell nanowires include those with a ferromagnetic core (e.g., iron, cobalt, nickel, manganese, as well as their oxides and alloys formed with one or more of these elements), with a shell formed of a metal, a metal alloy, a metal oxide, carbon, or any combination thereof (e.g., silver, copper, gold, platinum, ZnO, ZnO(i), ZnO:Al, ZnO:B, SnO₂:F, Cd₂SnO₄, CdS, ZnS, TiO₂, ITO, graphene, and other materials listed as suitable additives herein). A particular example of a core-shell nanowire is one with an Ag core and an Au shell (or a platinum shell or another type of shell) surrounding the silver core to reduce or prevent oxidation of the silver core.

Additives can also include, for example, functional agents such as metamaterials, in place or, in combination with, electrically conductive materials and semiconductors. Metamaterials and related artificial composite structures with unique electromagnetic properties can include, for example, split ring resonators, ring resonators, cloaking devices, nanostructured antireflection layers, high absorbance layers, perfect lenses, concentrators, microconcentrators, focusers of electromagnetic energy, couplers, and the like. Additives can also include, for example, materials that reflect, absorb, or scatter electromagnetic radiation, such as any one or more of infrared radiation, ultraviolet radiation, and x-ray radiation. Such materials include, for example, Au, Ge, TiO₂, Si, Al₂O₃, CaF₂, ZnS, GaAs, ZnSe, KCl, ITO, tin oxide, ZnO, MgO, CaCO₃, benzophenones, benzotriazole, hindered amine light stabilizers, cyanoacrylate, salicyl-type compounds, Ni, Pb, Pd, Bi, Ba, BaSO₄, steel, U, Hg, metal oxides, or any combination thereof. Additional examples of materials for additives include PbSO₄, SnO₂, Ru, As, Te, In, Pt, Se, Cd, S, Sn, Zn, copper indium diselenide (“CIS”), Cr, Ir, Nd, Y, ceramics (e.g., a glass), silica, organic fluorescent dyes, or any combination thereof.

Additives can also include, for example, polymer-containing nanotubes, polymer-containing nanoparticles, polymer-containing nanowires, semiconducting nanotubes, insulated nanotubes, nanoantennas, additives formed of ferromagnetic materials, additives formed of a ferromagnetic core and a highly conducting shell, organometallic nanotubes, metallic nanoparticles or microparticles, additives formed of piezoelectric materials, additives formed of quantum dots, additives with dopants, optical concentrating and trapping structures, optical rectennas, nano-sized flakes, nano-coaxial structures, waveguiding structures, metallic nanocrystals, semiconducting nanocrystals, as well as additives formed of multichromic agents, oxides, chemicochromic agents, alloys, piezochromic agents, thermochromic agents, photochromic agents, radiochromic agents, electrochromic agents, metamaterials, silver nitrate, magnetochromic agents, toxin neutralizing agents, aromatic substances, catalysts, wetting agents, salts, gases, liquids, colloids, suspensions, emulsions, plasticizers, UV-resistance agents, luminescent agents, antibacterial agents, antistatic agents, behentrimonium chloride, cocamidopropyl betaine, phosphoric acid esters, phylethylene glycol ester, polyols, dinonylnaphthylsulfonic acid, ruthenium metalorganic dye, titanium oxide, scratch resistant agents, graphene, copper phthalocyanine, anti-fingerprint agents, anti-fog agents, UV-resistant agents, tinting agents, anti-reflective agents, infrared-resistant agents, high reflectivity agents, optical filtration agents, fragrance, de-odorizing agents, resins, lubricants, solubilizing agents, stabilizing agents, surfactants, fluorescent agents, activated charcoal, toner agents, circuit elements, insulators, conductors, conductive fluids, magnetic additives, electronic additives, plasmonic additives, dielectric additives, resonant additives, luminescent molecules, fluorescent molecules, cavities, lenses, cold cathodes, electrodes, nanopyramids, resonators, sensors, actuators, transducers, transistors, lasers, oscillators, photodetectors, photonic crystals, conjugated polymers, nonlinear elements, composites, multilayers, chemically inert agents, phase-shifting structures, amplifiers, modulators, switches, photovoltaic cells, light-emitting diodes, couplers, antiblock and antislip agents (e.g., diatomaceous earth, talc, calcium carbonate, silica, and silicates); slip agents and lubricants (e.g., fatty acid amides, erucamide, oleamide, fatty acid esters, metallic stearates, waxes, and amide blends), antioxidants (e.g., amines, phenolics, organophosphates, thioesters, and deactivators), antistatic agents (e.g., cationic antistats, quaternary ammonium salts and compounds, phosphonium, sulfonium, anionic counterstats, electrically conductive polymers, amines, and fatty acid esters), biocides (e.g., 10, 10′-oxybisphenoxarsine (or OBPA), amine-neutralized phosphate, zinc 2-pyridinethianol-1-oxide (or zinc-OMADINE),2-n-octyl-4-isothiazolin-3-one, DCOIT, TRICLOSAN, CAFTAN, and FOLPET), light stabilizers (e.g., ultraviolet absorbers, benzophenone, benzotriazole, benzoates, salicylates, nickel organic complexes, hindered amine light stabilizers (or HALS), and nickel-containing compounds), electrically conducting polymer (e.g., polyaniline, poly(acetylene), poly(pyrrole), poly(thiophene), poly(p-phenylene sulfide), poly(p-phenylene vinylene) (or PPV), poly(3-alkylthiophene), olyindole, polypyrene, polycarbazole, polyazulene, polyazepine, poly(fluorene), polynaphthalene, melanins, poly(3,4-ethylenedioxythiophene) (or PEDOT), poly(styrenesulfonate) (or PSS), PEDOT-PSS, PEDOT-polymethacrylic acid (or PEDOT-PMA), poly(3-hexylthiophene) (or P3HT), poly(3-octylthiophene) (or P3OT), poly(C-61-butyric acid-methyl ester) (or PCBM), and poly[2-methoxy-5-(2′-ethyl-hexyloxy)-1,4-phenylene vinylene] (or MEH-PPV)), any material listed as a suitable host material herein, or any combination thereof.

For certain implementations, high aspect ratio additives are desirable, such as in the form of nanowires, nanotubes, and combinations thereof. For example, desirable additives include nanotubes formed of carbon or other materials (e.g., MWNTs, SWNTs, graphitized MWNTs, graphitized SWNTs, modified MWNTs, modified SWNTs, and polymer-containing nanotubes), nanowires formed of a metal, a metal oxide, a metal alloy, or other materials (e.g., Ag nanowires, Cu nanowires, zinc oxide nanowires (undoped or doped by, for example, aluminum, boron, fluorine, and others), tin oxide nanowires (undoped or doped by, for example, fluorine), cadmium tin oxide nanowires, ITO nanowires, polymer-containing nanowires, and Au nanowires), as well as other materials that are electrically conductive or semiconducting and having a variety of shapes, whether spherical, pyramidal, or otherwise. Additional examples of additives include those formed of activated carbon, graphene, carbon black, ketjen black, and nanoparticles formed of a metal, a metal oxide, a metal alloy, or other materials (e.g., Ag nanoparticles, Cu nanoparticles, zinc oxide nanoparticles, ITO nanoparticles, and Au nanoparticles).

In general, a host material can have a variety of shapes and sizes, can be transparent, translucent, or opaque, can be flexible, bendable, foldable or rigid, can be electromagnetically opaque or electromagnetically transparent, and can be electrically conductive, semiconducting, or insulating. The host material can be in the form of a substrate, or can be in the form of a coating or multiple coatings disposed on top of a substrate or another material. Examples of suitable host materials include organic materials, inorganic materials, and hybrid organic-inorganic materials. For example, a host material can include a thermoplastic polymer, a thermoset polymer, an elastomer, or a copolymer or other combination thereof, such as selected from polyolefin, polyethylene (or PE), polypropylene (or PP), polyacrylate, polyester, polysulphone, polyamide, polyimide, polyurethane, polyvinyl, fluoropolymer, polycarbonate (or PC), polysulfone, polylactic acid, polymer based on allyl diglycol carbonate, nitrile-based polymer, acrylonitrile butadiene styrene (or ABS), phenoxy-based polymer, phenylene ether/oxide, a plastisol, an organosol, a plastarch material, a polyacetal, aromatic polyamide, polyamide-imide, polyarylether, polyetherimide, polyarylsulfone, polybutylene, polycarbonate, polyketone, polymethylpentene, polyphenylene, polystyrene, high impact polystyrene, polymer based on styrene maleic anhydride, polymer based on polyllyl diglycol carbonate monomer, bismaleimide-based polymer, polyallyl phthalate, thermoplastic polyurethane, high density polyethylene, low density polyethylene, copolyesters (e.g., available under the trademark Tritan™), polyvinyl chloride (or PVC), acrylic-based polymer, polyethylene terephthalate glycol (or PETG), polyethylene terephthalate (or PET), epoxy, epoxy-containing resin, melamine-based polymer, silicone and other silicon-containing polymers (e.g., polysilanes and polysilsesquioxanes), polymers based on acetates, poly(propylene fumarate), poly(vinylidene fluoride-trifluoroethylene), poly-3-hydroxybutyrate polyesters, polyamide, polycaprolactone, polyglycolic acid (or PGA), polyglycolide, polylactic acid (or PLA), polylactide acid plastics, polyphenylene vinylene, electrically conducting polymer (e.g., polyaniline, poly(acetylene), poly(pyrrole), poly(thiophene), poly(p-phenylene sulfide), poly(p-phenylene vinylene) (or PPV), poly(3-alkylthiophene), olyindole, polypyrene, polycarbazole, polyazulene, polyazepine, poly(fluorene), polynaphthalene, melanins, poly(3,4-ethylenedioxythiophene) (or PEDOT), poly(styrenesulfonate) (or PSS), PEDOT-PSS, PEDOT-polymethacrylic acid (or PEDOT-PMA), poly(3-hexylthiophene) (or P3HT), poly(3-octylthiophene) (or P3OT), poly(C-61-butyric acid-methyl ester) (or PCBM), and poly[2-methoxy-5-(2′-ethyl-hexyloxy)-1,4-phenylene vinylene] (or MEH-PPV)), polyolefins, liquid crystal polymers, polyurethane, polyester, copolyester, poly(methyl mechacrylate) copolymer, tetrafluoroethylene-based polymer, sulfonated tetrafluoroethylene copolymer, ionomers, fluorinated ionomers, polymer corresponding to, or included in, polymer electrolyte membranes, ethanesulfonyl fluoride-based polymer, polymer based on 2-[1-[difluoro-[(trifluoroethenyl)oxy]methyl]-1,2,2,2-tetrafluoroethoxy]-1,1,2,2,-tetrafluoro-(with tetrafluoro ethylene, tetrafluoroethylene-perfluoro-3,6-dioxa-4-methyl-7-octenesulfonic acid copolymer), polypropylene, polybutene, polyisobutene, polyisoprene, polystyrene, polylactic acid, polyglycolide, polyglycolic acid, polycaprolactone, polymer based on vinylidene fluoride, polymer based on trifluoroethylene, poly(vinylidene fluoride-trifluoroethylene), polyphenylene vinylene, polymer based on copper phthalocyanine, graphene, poly(propylene fumarate), cellophane, cuprammonium-based polymer, rayon, and biopolymers (e.g., cellulose acetate (or CA), cellulose acetate butyrate (or CAB), cellulose acetate propionate (or CAP), cellulose propionate (or CP), polymers based on urea, wood, collagen, keratin, elastin, nitrocellulose, plastarch, celluloid, bamboo, bio-derived polyethylene, carbodiimide, cartilage, cellulose nitrate, cellulose, chitin, chitosan, connective tissue, copper phthalocyanine, cotton cellulose, elastin, glycosaminoglycans, linen, hyaluronic acid, nitrocellulose, paper, parchment, plastarch, starch, starch-based plastics, vinylidene fluoride, and viscose), or any monomer, copolymer, blend, or other combination thereof. Additional examples of suitable host materials include ceramic (e.g., SiO₂-based glass; SiOₓ-based glass; TiOₓ-based glass; other titanium, cerium, magnesium analogues of SiOₓ-based glass; spin-on glass; glass formed from sol-gel processing, silane precursor, siloxane precursor, silicate precursor, tetraethyl orthosilicate, silane, siloxane, phosphosilicates, spin-on glass, silicates, sodium silicate, potassium silicate, a glass precursor, a ceramic precursor, silsesquioxane, metallasilsesquioxanes, polyhedral oligomeric silsesquioxanes, halosilane, polyimide, PMMA photoresist, sol-gel, silicon-oxygen hydrides, silicones, stannoxanes, silathianes, silazanes, polysilazanes, metallocene, titanocene dichloride, vanadocene dichloride; and other types of glasses), ceramic precursor, polymer-ceramic composite, polymer-wood composite, polymer-carbon composite (e.g., formed of ketjen black, activated carbon, carbon black, graphene, and other forms of carbon), polymer-metal composite, polymer-oxide, or any combination thereof.

A host material can be, for example, n-doped, p-doped, or un-doped. Embedded additives can be, for example, n-doped, p-doped, or un-doped. If the host material is electrically conductive or semiconducting, additives that are n-doped, p-doped, or both, can be used to form p-n junction devices, transistors, diodes, light-emitting diodes, sensors, memory devices, solar energy to electrical conversion devices, and so forth.

At least one difference between the configuration of FIG. 1A and certain surface-embedded structures described herein (e.g., as illustrated in FIG. 1D through FIG. 1H and FIG. 2A through FIG. 2G) is that, characteristic of bulk incorporation, the substrate 104 of FIG. 1A has the additives 102 distributed randomly and relatively uniformly throughout the substrate 104. In contrast, in the surface-embedded structures described herein, additives can be largely confined to a “planar” or “planar-like” embedding region of a host material, leading to decreased topological disorder of the additives and increased occurrence of junction formation between the additives for improved electrical conductivity. Although an embedding region is sometimes referred as “planar,” it will be understood that such embedding region is typically not strictly two-dimensional, as the additives themselves are typically three-dimensional. Rather, “planar” can be used in a relative sense, with a relatively thin, slab-like (or layered) local concentration of the additives within a certain region of the host material, and with the additives largely absent from a remainder of the host material. It will also be understood that an embedding region can be referred as “planar,” even though such an embedding region can have a thickness that is greater than (e.g., several times greater than) a characteristic dimension of additives, such as in FIG. 1F, FIG. 2A, and FIG. 2B. An embedding region can be located adjacent to one side of a host material, adjacent to a middle of the host material, or adjacent to any arbitrary location along a thickness direction of the host material, and multiple embedding regions can be located adjacent to one another or spaced apart from one another within the host material. Each embedding region can include one or more types of additives, and embedding regions (which are located in the same host material) can include different types of additives. By confining additives to a set of “planar” embedding regions of a host material (as opposed to randomly throughout the host material), a higher electrical conductivity can be achieved for a given amount of the additives per unit of area. Any additives not confined to an embedding region represent an excess amount of additives that can be omitted.

At least one difference between the configuration of FIG. 1B and certain surface-embedded structures described herein (e.g., as illustrated in FIG. 1D through FIG. 1H and FIG. 2A through FIG. 2G) is that, characteristic of a conventional coating, the coating 110 of FIG. 1B has the additives 108 mixed throughout the coating 110, which is disposed on top of the substrate 112. Referring to the coating 110 itself, the coating 110 features a configuration similar to that shown in FIG. 1A for the case of bulk incorporation, with the additives 108 distributed randomly and relatively uniformly throughout the coating 110. In contrast, in certain surface-embedded structures described herein, additives are not located uniformly throughout a coating, but rather can be largely confined to a “planar” or “planar-like” embedding region of a substrate, without any coating or other secondary material needed for binding the additives to the substrate, while, in other surface-embedded structures (e.g., as illustrated in FIG. 1G and FIG. 2G), additives can be largely confined to a “planar” or “planar-like” embedding region of a coating, rather than located uniformly throughout the coating. Confining additives to a “planar” or “planar-like” embedding region leads to decreased topological disorder of the additives and increased occurrence of junction formation between the additives for improved electrical conductivity. Also, the coating 110 of FIG. 1B can be susceptible to damage, as an exposed material on top of the coating 110 can be readily removed with scotch tape, a sticky or abrasive force, or other force, and can have a tendency to migrate off the surface. The coating 110 containing the additives 108 can also delaminate, crack, peel, bubble, or undergo other deformation, which can be overcome by certain surface-embedded structures described herein in which additives are directly embedded into a substrate, without any coating or other secondary material needed for the purposes of binding. Moreover, the surface of the coating 110 can be quite rough (e.g., arising from topological disorder of the additives 108 in which some of the additives 108 extend out from the surface of the coating 110), which can cause electrical shorts and prevent intimate contact with an adjacent device layer. This is in contrast to the surface-embedded structures described herein, which can feature durable, smooth surfaces. In the case where additives are substantially or fully embedded into a host material (e.g., as illustrated in FIG. 1E and FIG. 1F), an embedding surface of the resulting surface-embedded structure is quite smooth (e.g., having a smoothness or a roughness substantially comparable to that of the host material in the absence of the embedded additives), with none, no greater than about 1%, no greater than about 5%, no greater than about 10%, no greater than about 25%, or no greater than about 50% of a surface area of the embedding surface occupied by exposed additives (e.g., as measured by taking a top view of the embedding surface or other 2-dimensional representation of the embedding surface, and determining percentage surface area coverage arising from the exposed additives).

At least one difference between the configuration of FIG. 1C and certain surface-embedded structures described herein (e.g., as illustrated in FIG. 1D through FIG. 1H and FIG. 2A through FIG. 2G) is that, characteristic of surface deposition, the additives 116 are disposed on top of the substrate 118, without any embedding of the additives 116 into the substrate 118. The surface-deposited structure 114 of FIG. 1C can be susceptible to damage, as the deposited material on top of the substrate 118 can be readily removed with scotch tape, a sticky or abrasive force, or other force, and can have a tendency to migrate off the surface. Also, the surface of the surface-deposited structure 114 is quite porous (e.g., arising from gaps between the surface-deposited additives 116, from stacking of the additives 116 on top of one another, or both), which can create challenges in achieving adequate infiltration of another material coated or otherwise applied on top of the surface-deposited additives 116, thereby resulting in voids or other interfacial defects. Moreover, the surface of the surface-deposited structure 114 can be quite rough, which can cause electrical shorts and prevent intimate contact with an adjacent device layer. This is in contrast to the surface-embedded structures described herein, which can feature durable, relatively non-porous, smooth surfaces. In the case where additives are substantially or fully embedded into a host material (e.g., as illustrated in FIG. 1E and FIG. 1F), an embedding surface of the resulting surface-embedded structure is quite smooth (e.g., having a smoothness or a roughness substantially comparable to that of the host material in the absence of the embedded additives), with none, no greater than about 1%, no greater than about 5%, no greater than about 10%, no greater than about 25%, or no greater than about 50% of a surface area of the embedding surface occupied by exposed additives (e.g., as measured by taking a top view of the embedding surface or other 2-dimensional representation of the embedding surface, and determining percentage surface area coverage arising from the exposed additives). Moreover, the surface-deposited structure 114 can have a higher sheet resistance or lower conductivity than the surface-embedded structures described herein.

In some embodiments, surface-embedded structures can have additives embedded into a host material from about 10% (or less, such as from about 0.1%) by volume into an embedding surface and up to about 100% by volume into the embedding surface, and can have the additives exposed at varying surface area coverage, such as from about 0.1% (or less) surface area coverage up to about 99.9% (or more) surface area coverage. For example, in terms of a volume of an additive embedded below the embedding surface relative to a total volume of the additive, at least one additive can have an embedded volume percentage (or a population of the additives can have an average embedded volume percentage) in the range of about 10% to about 100%, such as from 10% to about 50%, or from about 50% to about 100%.

In some embodiments, surface-embedded structures can have an embedding region with a thickness greater than a characteristic dimension of the additives used (e.g., for nanowires, greater than a diameter of an individual nanowire or an average diameter across the nanowires), with the additives largely confined to the embedding region with the thickness less than an overall thickness of the host material. For example, the thickness of the embedding region can be no greater than about 80% of the overall thickness of the host material, such as no greater than about 50%, no greater than about 40%, no greater than about 30%, no greater than about 20%, no greater than about 10%, or no greater than about 5% of the overall thickness.

In some embodiments, additives can be embedded into a host material by varying degrees relative to a characteristic dimension of the additives used (e.g., for nanowires, relative to a diameter of an individual nanowire or an average diameter across the nanowires). For example, in terms of a distance of a furthest embedded point on an additive below an embedding surface, at least one additive can be embedded to an extent of more than about 100% of the characteristic dimension, or can be embedded to an extent of not more than about 100% of the characteristic dimension, such as at least about 5% or about 10% and up to about 80%, up to about 50%, or up to about 25% of the characteristic dimension. As another example, a population of the additives, on average, can be embedded to an extent of more than about 100% of the characteristic dimension, or can be embedded to an extent of not more than about 100% of the characteristic dimension, such as at least about 5% or about 10% and up to about 80%, up to about 50%, or up to about 25% of the characteristic dimension. As will be understood, the extent at which additives are embedded into a host material can impact a roughness of an embedding surface, such as when measured as an extent of variation of heights across the embedding surface (e.g., a standard deviation relative to an average height). Comparing, for example, FIG. 1D versus FIG. C, a roughness of the surface-embedded structure 120 of FIG. 1D is less than a characteristic dimension of the partially embedded additives 130, while a roughness of the structure 114 of FIG. 1C is at least a characteristic dimension of the superficially deposited additives 116 and can be about 2 times (or more) the characteristic dimension (e.g., as a resulting of stacking of the additives 116 on top of one another).

In some embodiments, at least one additive can extend out from an embedding surface of a host material from about 0.1 nm to about 1 cm, such as from about 1 nm to about 50 nm, from about 50 nm to 100 nm, or from about 100 nm to about 100 microns. In other embodiments, a population of additives, on average, can extend out from an embedding surface of a host material from about 0.1 nm to about 1 cm, such as from about 1 nm to about 50 nm, from about 50 nm to 100 nm, or from about 100 nm to about 100 microns. In other embodiments, substantially all of a surface area of a host material (e.g., an area of an embedding surface) is occupied by additives. In other embodiments, up to about 100% or up to about 75% of the surface area is occupied by additives, such as up to about 50% of the surface area, up to about 25% of the surface area, up to about 10%, up to about 5%, up to about than 3% of the surface area, or up to about 1% of the surface area is occupied by additives. Additives need not extend out from an embedding surface of a host material, and can be localized entirely below the embedding surface The degree of embedding and surface coverage of additives for a surface-embedded structure can be selected in accordance with a particular device or application. For example, a device operating based upon capacitance on the surface-embedded structure can specify a deeper degree of embedding and lower surface coverage of the additives, while a device operating based upon the flow of an electric current through or across the surface-embedded structure can specify a lesser degree of embedding and higher surface coverage of the additives.

In some embodiments, if nanowires are used as additives, characteristics that can influence electrical conductivity include, for example, nanowire density or loading level, surface area coverage, nanowire length, nanowire diameter, uniformity of the nanowires, material type, and purity. There can be a preference for nanowires with a low junction resistance and a low bulk resistance in some embodiments. For attaining higher electrical conductivity while maintaining high transparency, thinner diameter, longer length nanowires can be used (e.g., with relatively large aspect ratios to facilitate nanowire junction formation and in the range of about 50 to about 2,000, such as from about 50 to about 1,000, or from about 100 to about 800), and metallic nanowires, such as Ag, Cu, and Au nanowires, can be used. Using nanowires as additives to form nanowire networks, such as Ag nanowire networks, can be desirable for some embodiments. Other metallic nanowires, non-metallic nanowires, such as ZnO, ZnO(i), ZnO:Al, ZnO:B, SnO₂:F, Cd₂SnO₄, CdS, ZnS, TiO₂, ITO, and other oxide nanowires, also can be used. Additives composed of semiconductors with band gaps outside the visible optical spectrum energies (e.g., <1.8 eV and >3.1 eV) or approximately near or outside this range, can be used to create TCEs with high optical transparency in that visible light will typically not be absorbed by the band energies or by interfacial traps therein. Various dopants can be used to tune the conductivity of these aforementioned semiconductors, taking into account the shifted Fermi levels and band edges via the Moss-Burstein effect. The nanowires can be largely uniform or monodisperse in terms of dimensions (e.g., diameter and length), such as the same within about 5% (e.g., a standard deviation relative to an average diameter or length), the same within about 10%, the same within about 15%, or the same within about 20%. Purity can be, for example, at least about 50%, at least about 75%, at least about 85%, at least about 90%, at least about 95%, at least about 99%, at least about 99.9%, or at least about 99.99%. Surface area coverage of nanowires can be, for example, up to about 100%, less than about 100%, up to about 75%, up to about 50%, up to about 25%, up to about 10%, up to about 5%, up to about 3%, or up to about 1%. Ag nanowires can be particularly desirable for certain embodiments, since silver oxide, which can form (or can be formed) on surfaces of Ag nanowires as a result of oxidation, is electrically conductive. Also, core-shell nanowires (e.g., silver core with Au or platinum shell) also can decrease junction resistance.

In some embodiments, if nanotubes are used as additives (whether formed of carbon, a metal, a metal alloy, a metal oxide, or another material), characteristics that can influence electrical conductivity include, for example, nanotube density or loading level, surface area coverage, nanotube length, nanotube inner diameter, nanotube outer diameter, whether single-walled or multi-walled nanotubes are used, uniformity of the nanotubes, material type, and purity. There can be a preference for nanotubes with a low junction resistance in some embodiments. For reduced scattering in the context of certain devices such as displays, nanotubes, such as carbon nanotubes, can be used to form nanotube networks. Alternatively, or in combination, smaller diameter nanowires can be used to achieve a similar reduction in scattering relative to use of nanotubes. The nanotubes can be largely uniform or monodisperse in terms of dimensions (e.g., outer diameter, inner diameter, and length), such as the same within about 5% (e.g., a standard deviation relative to an average outer/inner diameter or length), the same within about 10%, the same within about 15%, or the same within about 20%. Purity can be, for example, at least about 50%, at least about 75%, at least about 85%, at least about 90%, at least about 95%, at least about 99%, at least about 99.9%, or at least about 99.99%. Surface area coverage of nanotubes can be, for example, up to about 100%, less than about 100%, up to about 75%, up to about 50%, up to about 25%, up to about 10%, up to about 5%, up to about 3%, or up to about 1%.

It should be understood that the number of additive types can be varied for a given device or application. For example, either, or a combination, of Ag nanowires, Cu nanowires, and Au nanowires can be used along with ITO nanoparticles to yield high optical transparency and high electrical conductivity. Similar combinations include, for example, either, or a combination, of Ag nanowires, Cu nanowires, and Au nanowires along with any one or more of ITO nanowires, ZnO nanowires, ZnO nanoparticles, Ag nanoparticles, Au nanoparticles, SWNTs, MWNTs, fullerene-based materials (e.g., carbon nanotubes and buckyballs), and ITO nanoparticles. The use of ITO nanoparticles or nanowires can provide additional functionality, such as by serving as a buffer layer to adjust a work function in the context of TCEs for solar cells or to provide a conductive path for the flow of an electric current, in place of, or in combination, with a conductive path provided by other additives. Virtually any number of different types of additives can be embedded in a host material.

In some embodiments, additives are initially provided as discrete objects. Upon embedding into a host material, the host material can envelop or surround the additives such that the additives become aligned or otherwise arranged within a “planar” or “planar-like” embedding region. In some embodiments for the case of additives such as nanowires, nanotubes, microwires, microtubes, or other additives with an aspect ratio greater than 1, the additives become aligned such that their lengthwise or longitudinal axes are largely confined to within a range of angles relative to a horizontal plane, or another plane corresponding, or parallel, to a plane of an embedding surface. For example, the additives can be aligned such that their lengthwise or longest-dimension axes, on average, are confined to a range from about −45° to about +45° relative to the horizontal plane, such as from about −35° to about +35°, from about −25° to about +25°, from about −15° to about +15°, from about −5° to about +5°, or from about −1° to about +1°. In this example, little or substantially none of the additives can have their lengthwise or longitudinal axes oriented outside of the range from about −45° to about +45° relative to the horizontal plane. Within the embedding region, neighboring additives can contact one another in some embodiments. Such contact can be improved using longer aspect ratio additives, while maintaining a relatively low surface area coverage for desired transparency. In some embodiments, contact between additives, such as nanowires, nanoparticles, microwires, and microparticles, can be increased through sintering or annealing, such as low temperature sintering at temperatures of about 50° C., about 125° C., about 150° C., about 175° C., or about 200° C., or in the range of about 50° C. to about 125° C., about 100° C. to about 125° C., about 125° C. to about 150° C., about 150° C. to about 175° C., or about 175° C. to about 200° C., flash sintering, sintering through the use of redox reactions to cause deposits onto additives to grow and fuse the additives together, or any combination thereof. For example, in the case of Ag or Au additives, Ag ions or Au ions can be deposited onto the additives to cause the additives to fuse with neighboring additives. High temperature sintering at temperatures at or above about 200° C. is also contemplated. It is also contemplated that little or no contact is needed for certain applications and devices, such as for anti-dust shields, anti-static shields, electromagnetic interference/radio frequency shields, where charge tunneling or hopping provides sufficient electrical conductivity in the absence of actual contact, or where a host material or a coating on top of the host material may itself be electrically conductive. Such applications and devices can operate with a sheet resistance up to about 10⁶ Ω/sq or more. Individual additives can be separated by electrical and quantum barriers for electron transfer.

The following provides additional advantages of the surface-embedded structures described herein, relative to the configurations illustrated in FIG. 1A through FIG. 1C. Unlike the configuration of FIG. 1A, a uniform distribution of additives throughout an entire bulk of a host material is not required to attain desired characteristics. Indeed, there is a preference in at least some embodiments that additives are largely confined to a “planar” or “planar-like” embedding region of a host material. In practice, it can be difficult to actually attain an uniform distribution as depicted in FIG. 1A, arising from non-uniform mixing and agglomeration and aggregation of additives. Unlike the configuration of FIG. 1B, additives can be embedded into a host material, rather than mixed throughout a coating and applied on top of the host material. In embedding the additives in such manner, the resulting surface-embedded structure can have a higher durability. Also, similarly to issues associated with bulk incorporation, conventional coatings can be susceptible to non-uniform mixing and agglomeration, which can be avoided or reduced with the surface-embedded structures described herein. Furthermore, conventional coatings can be quite rough, particularly on the nanometer and micron level. In contrast, and arising, for example, from embedding of additives and alignment of the additives within a host material, the surface-embedded structures can have a decreased roughness compared to conventional coatings, thereby serving to avoid or reduce instances of device failure (e.g., shunting from nanowire penetration of a device). Unlike the configuration of FIG. 1C, additives are partially or fully embedded into a host material, rather than superficially disposed on top of a surface, resulting in a decreased roughness compared to superficially deposited additives and higher durability and conductivity. In some embodiments, when embedding nanowires, polymer chains of a host material can hold the nanowires together, pulling them closer and increasing conductivity.

The surface-embedded structures can be quite durable. In some embodiments, such durability is in combination with rigidity and robustness, and, in other embodiments, such durability is in combination with the ability to be flexed, rolled, bent, folded, amongst other physical actions, with, for example, no greater than about 50%, no greater than about 20%, no greater than about 15%, no greater than about 10%, no greater than about 5%, no greater than about 3%, or substantially no decrease in transmittance, and no greater than about 50%, no greater than about 20%, no greater than about 15%, no greater than about 10%, no greater than about 5%, no greater than about 3%, or substantially no increase in resistance. In some embodiments, the surface-embedded structures are largely immune to durability issues of conventional coatings, and can survive a standard Scotch Tape Test used in the coatings industry and yield substantially no decrease, or no greater than about 5% decrease, no greater than about 10% decrease, no greater than about 15% decrease, or no greater than about 50% decrease in observed transmittance, and yield substantially no increase, or no greater than about 5% increase, no greater than about 10% increase, no greater than about 15% increase, or no greater than about 50% increase in observed resistance. In some embodiments, the surface-embedded structures can also survive rubbing, scratching, flexing, physical abrasion, thermal cycling, chemical exposure, and humidity cycling with substantially no decrease, no greater than about 50% decrease, no greater than about 20% decrease, no greater than about 15% decrease, no greater than about 10% decrease, no greater than about 5% decrease, or no greater than about 3% decrease in observed transmittance, and with substantially no increase, no greater than about 50% increase, no greater than about 20% increase, no greater than about 15% increase, no greater than about 10% increase, no greater than about 5% increase, or no greater than about 3% increase in observed resistance. This enhanced durability can result embedding of additives within a host material, such that the additives are physically or chemically held inside the host material by molecular chains or other components of the host material. In some cases, flexing or pressing can be observed to increase conductivity.

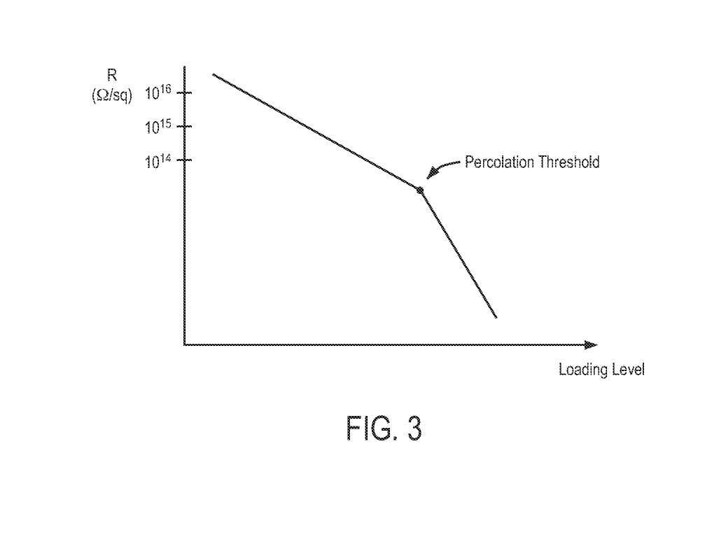

Another advantage of the surface-embedded structures is that an electrical percolation threshold can be attained using a lesser amount of additives. Stated in another way, electrical conductivity can be attained using less additive material, thereby saving additive material and associated cost and increasing transparency. As will be understood, an electrical percolation threshold is typically reached when a sufficient amount of additives is present to allow percolation of electrical charge from one additive to another additive, thereby providing a conductive path across at least portion of a network of additives. In some embodiments, an electrical percolation threshold can be observed via a change in slope of a logarithmic plot of resistance versus loading level of additives as illustrated in FIG. 3A. A lesser amount of additive material can be used since additives are largely confined to a “planar” or “planar-like” embedding region, thereby greatly reducing topological disorder and resulting in a higher probability of inter-additive (e.g., inter-nanowire or inter-nanotube) junction formation compared to the configurations of FIG. 1A through FIG. 1C. In other words, because the additives are confined to a thin embedding region in the host material, as opposed to dispersed through the thickness of the host material, the probability that the additives will interconnect and form junctions can be greatly increased. In some embodiments, an electrical percolation threshold can be attained at a loading level of additives in the range of about 0.001 μg/cm² to about 100 μg/cm² (or higher), such as from about 0.01 μg/cm² to about 100 μg/cm², from about 10 μg/cm² to about 100 μg/cm², from 0.01 μg/cm² to about 0.4 μg/cm², from about 0.5 μg/cm² to about 5 μg/cm², or from about 0.8 μg/cm² to about 3 μg/cm² for certain additives such as silver nanowires. These loading levels can be varied according to dimensions, material type, spatial dispersion, and other characteristics of additives.

In addition, a lesser amount of additives can be used (e.g., as evidenced by a thickness of an embedding region) to achieve a network-to-bulk transition, which is a parameter representing a transition of a thin layer from exhibiting effective material properties of a sparse two-dimensional conducting network to one exhibiting effective properties of a three-dimensional conducting bulk material. By confining additives (e.g., Ag nanowires, Cu nanowires, multi-walled carbon nanotubes (“MWCNTs”), singled-walled carbon nanotubes (“SWCNTs”), or any combination thereof) to a “planar” or “planar-like” embedding region, a lower sheet resistance can be attained at specific levels of solar flux-weighted transmittance. Furthermore, in some embodiments, carrier recombination can be reduced with the surface-embedded structures due to the reduction or elimination of interfacial defects associated with a separate coating or other secondary material into which additives are mixed.

To expound further on these advantages, a network of additives can be characterized by a topological disorder and by contact resistance. Topologically, above a critical density of additives and above a critical density of additive-additive (e.g., nanowire-nanowire, nanotube-nanotube, or nanotube-nanowire) junctions, electrical current can readily flow from a source to a drain. A “planar” or “planar-like” network of additives can reach a network-to-bulk transition with a reduced thickness, represented in terms of a characteristic dimension of the additives (e.g., for nanowires, relative to a diameter of an individual nanowire or an average diameter across the nanowires). For example, an embedding region can have a thickness up to about 5 times (or more) the characteristic dimension, such as up to about 4 times, up to about 3 times, or up to about 2 times the characteristic dimension, and down to about 0.05 or about 0.1 times the characteristic dimension, allowing devices to be thinner while increasing optical transparency and electrical conductivity. According, the surface-embedded structures described herein provide, in some embodiments, an embedding region with a thickness up to about nxd (in terms of nm) within which are localized additives having a characteristic dimension of d (in terms of nm), where n=2, 3, 4, 5, or higher.

Yet another advantage of the surface-embedded structures is that, for a given level of electrical conductivity, the structures can yield higher transparency. This is because less additive material can be used to attain that level of electrical conductivity, in view of the efficient formation of additive-additive junctions for a given loading level of additives. As will be understood, a transmittance of a thin conducting material (e.g., in the form of a film) can be expressed as a function of its sheet resistance Rₛₕₑₑₜ and an optical wavelength, as given by the following approximate relation for a thin film:

$$T ( λ ) = {( 1 + \frac{188.5}{{R}_{•}} \frac{{σ}_{Op} ( λ )}{{σ}_{DC}} )}^{- 2} \qquad ( 1 )$$

where σ_{Op} and σ_{DC} are the optical and DC conductivities of the material, respectively. In some embodiments, Ag nanowire networks surface-embedded into flexible transparent substrates can have sheet resistances as low as about 3.2 Ω/sq or about 0.2 Ω/sq, or even lower. In other embodiments, transparent surface-embedded structures suitable for solar cells can reach up to about 85% (or more) for solar flux-weighted transmittance Tₛₒₗₐᵣ and a sheet resistances as low as about 20 Ω/sq (or below). In still other embodiments, a sheet resistance of ≦10 Ω/sq at ≧85% (e.g., at least about 85%, at least about 90%, or at least about 95%, and up to about 97%, about 98%, or more) solar flux-weighted transmittance can be obtained with the surface-embedded structures. It will be understood that transmittance can be measured relative to other ranges of optical wavelength, such as transmittance at a given wavelength of 550 nm, a human vision or photometric-weighted transmittance (e.g., from about 350 nm to about 700 nm), solar-flux weighted transmittance, transmittance at a given wavelength or range of wavelengths in the infrared range, and transmittance at a given wavelength or range of wavelengths in the ultraviolet range. It will also be understood that transmittance can be measured relative to a substrate (if present) (e.g., accounting for an underlying substrate that is below a host material with surface-embedded additives), or can be measured relative to air (e.g., without accounting for the underlying substrate). Unless otherwise specified herein, transmittance values are designated relative to a substrate (if present), although similar transmittance values (albeit with somewhat higher values) are also contemplated when measured relative to air. For some embodiments, a DC-to-optical conductivity ratio of surface-embedded structures can be at least about 100, at least about 115, at least about 300, at least about 400, or at least about 500, and up to about 600, up to about 800, or more.

Certain surface-embedded structures can include additives of Ag nanowires of average diameter in the range of about 1 nm to about 100 nm, about 10 nm to about 80 nm, about 20 nm to about 80 nm, or about 40 nm to about 60 nm, and an average length in the range of about 50 nm to about 1,000 μm, about 50 nm to about 500 μm, about 100 nm to about 100 μm, about 500 nm to 50 μm, about 5 μm to about 50 μm, about 20 μm to about 150 μm, about 5 μm to about 35 μm, about 25 μm to about 80 μm, about 25 μm to about 50 μm, or about 25 μm to about 40 μm. A top of an embedding region can be located about 0.0001 nm to about 100 μm below a top, embedding surface of a host material, such as about 0.01 nm to about 100 μm, about 0.1 nm to 100 μm below the embedding surface, about 0.1 nm to about 5 μm below the embedding surface, about 0.1 nm to about 3 μm below the embedding surface, about 0.1 nm to about 1 μm below the embedding surface, or about 0.1 nm to about 500 nm below the embedding surface. Nanowires embedded into a host material can protrude from an embedding surface from about 0% by volume and up to about 90%, up to about 95%, or up to about 99% by volume. For example, in terms of a volume of a nanowire exposed above the embedding surface relative to a total volume of the nanowire, at least one nanowire can have an exposed volume percentage (or a population of the nanowires can have an average exposed volume percentage) of up to about 1%, up to about 5%, up to about 20%, up to about 50%, or up to about 75% or about 95%. At a transmittance of about 85% or greater (e.g., solar flux-weighted transmittance or one measured at another range of optical wavelengths), a sheet resistance can be no greater than about 500 Ω/sq, no greater than about 400 Ω/sq, no greater than about 350 Ω/sq, no greater than about 300 Ω/sq, no greater than about 200 Ω/sq, no greater than about 100 Ω/sq, no greater than about 75 Ω/sq, no greater than about 50 Ω/sq, no greater than about 25 Ω/sq, no greater than about 10 Ω/sq, and down to about 1 Ω/sq or about 0.1 Ω/sq, or less. At a transmittance of about 90% or greater, a sheet resistance can be no greater than about 500 Ω/sq, no greater than about 400 Ω/sq, no greater than about 350 Ω/sq, no greater than about 300 Ω/sq, no greater than about 200 Ω/sq, no greater than about 100 Ω/sq, no greater than about 75 Ω/sq, no greater than about 50 Ω/sq, no greater than about 25 Ω/sq, no greater than about 10 Ω/sq, and down to about 1 Ω/sq or less. In some embodiments, a host material corresponds to a substrate with surface-embedded nanowires, and the host material can be transparent or opaque, can be flexible or rigid, and can be composed of, for example, PE, PET, PETG, polycarbonate, PVC, PP, acrylic-based polymer, ABS, ceramic, glass, or any combination thereof. In other embodiments, a substrate can be transparent or opaque, can be flexible or rigid, and can be composed of, for example, PE, PET, PETG, polycarbonate, PVC, PP, acrylic-based polymer, ABS, ceramic, glass, or any combination thereof, where the substrate is coated with an electrically conductive material, insulator, or semiconductor (e.g., a doped metal oxide or an electrically conductive polymer listed above) and with nanowires embedded into the coating.

Certain surface-embedded structures can include additives of either, or both, MWCNT and SWCNT of average outer diameter in the range of about 1 nm to about 100 nm, about 1 nm to about 10 nm, about 10 nm to about 50 nm, about 10 nm to about 80 nm, about 20 nm to about 80 nm, or about 40 nm to about 60 nm, and an average length in the range of about 50 nm to about 100 μm, about 100 nm to about 100 μm, about 500 nm to 50 μm, about 5 μm to about 50 μm, about 5 μm to about 35 μm, about 25 μm to about 80 μm, about 25 μm to about 50 μm, or about 25 μm to about 40 μm. A top of an embedding region can be located about 0.01 nm to about 100 μm below a top, embedding surface of a host material, such as about 0.1 nm to 100 μm below the embedding surface, about 0.1 nm to about 5 μm below the embedding surface, about 0.1 nm to about 3 μm below the embedding surface, about 0.1 nm to about 1 μm below the embedding surface, or about 0.1 nm to about 500 nm below the embedding surface. Nanotubes embedded into a host material can protrude from an embedding surface from about 0% by volume and up to about 90%, up to about 95%, or up to about 99% by volume. For example, in terms of a volume of a nanotube exposed above the embedding surface relative to a total volume of the nanotube (e.g., as defined relative to an outer diameter of a nanotube), at least one nanotube can have an exposed volume percentage (or a population of the nanotubes can have an average exposed volume percentage) of up to about 1%, up to about 5%, up to about 20%, up to about 50%, or up to about 75% or about 95%. At a transmittance of about 85% or greater (e.g., solar flux-weighted transmittance or one measured at another range of optical wavelengths), a sheet resistance can be no greater than about 500 Ω/sq, no greater than about 400 Ω/sq, no greater than about 350 Ω/sq, no greater than about 300 Ω/sq, no greater than about 200 Ω/sq, no greater than about 100 Ω/sq, no greater than about 75 Ω/sq, no greater than about 50 Ω/sq, no greater than about 25 Ω/sq, no greater than about 10 Ω/sq, and down to about 1 Ω/sq or less. At a transmittance of about 90% or greater, a sheet resistance can be no greater than about 500 Ω/sq, no greater than about 400 Ω/sq, no greater than about 350 Ω/sq, no greater than about 300 Ω/sq, no greater than about 200 Ω/sq, no greater than about 100 Ω/sq, no greater than about 75 Ω/sq, no greater than about 50 Ω/sq, no greater than about 25 Ω/sq, no greater than about 10 Ω/sq, and down to about 1 Ω/sq or about 0.1 Ω/sq, or less. In some embodiments, a host material corresponds to a substrate with surface-embedded nanotubes, and the host material can be transparent or opaque, can be flexible or rigid, and can be composed of, for example, PE, PET, PETG, polycarbonate, PVC, PP, PMMA, glass, polyimide, epoxy, acrylic-based polymer, ABS, ceramic, glass, or any combination thereof. In other embodiments, a substrate can be transparent or opaque, can be flexible or rigid, and can be composed of, for example, PE, PET, PETG, polycarbonate, PVC, PP, acrylic-based polymer, ABS, ceramic, glass, or any combination thereof, where the substrate is coated with an electrically conductive material, insulator, or semiconductor (e.g., a doped metal oxide or an electrically conductive polymer listed above) and with nanotubes embedded into the coating.

Data obtained for surface-embedded structures reveals unexpected findings. In particular, it was previously speculated that additives superficially deposited on top of a surface can yield greater electrically conductivity than additives physically embedded into a host material, since the host material (which is an insulator) was speculated to inhibit conducting ability of the additives. However, and unexpectedly, improved electrical conductivity was observed for surface-embedded structures, supporting the notion of favorable junction formation and network-to-bulk transition imposed by embedding the additives within a host material.

### Devices Including Surface-Embedded Structures

The surface-embedded structures described herein can be used as electrodes in a variety of devices, including any device that uses TCEs in the form of doped metal oxide coatings. Examples of suitable devices include solar cells (e.g., thin-film solar cells and crystalline silicon solar cells), display devices (e.g., flat panel displays, liquid crystal displays (“LCDs”), plasma displays, organic light emitting diode (“OLED”) displays, electronic-paper (“e-paper”), quantum dot displays, and flexible displays), solid-state lighting devices (e.g., OLED lighting devices), touch screen devices (e.g., projected capacitive touch screen devices and resistive touch screen devices), smart windows (or other windows), windshields, aerospace transparencies, electomagnetic interference shields, charge dissipation shields, and anti-static shields, as well as other electronic, optical, optoelectronic, quantum, photovoltaic, and plasmonic devices.

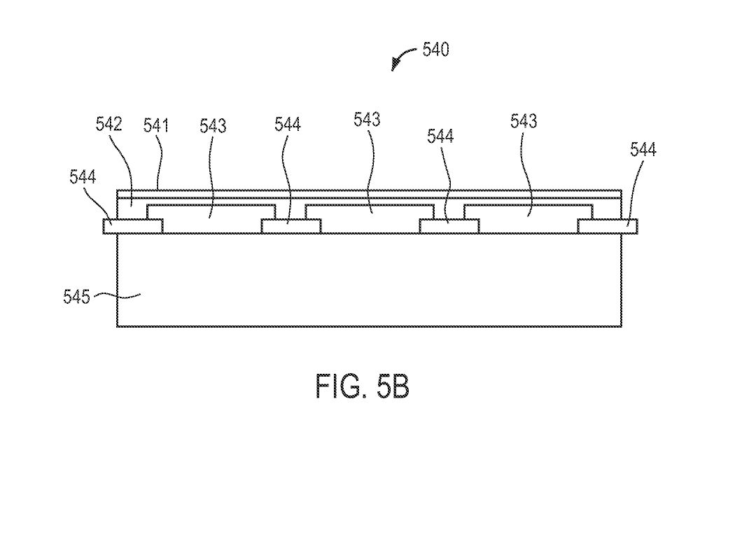

In some embodiments, the surface-embedded structures can be used as electrodes in LCDs. FIG. 5A illustrates a LCD 500 according to an embodiment of the invention. A backlight module 502 projects light through a thin-film transistor (“TFT”) substrate 506 and a bottom polarizer 504, which is disposed adjacent to a bottom surface of the TFT substrate 506. A TFT 508, a pixel electrode 510, and a storage capacitor 512 are disposed adjacent to a top surface of the TFT substrate 506 and between the TFT substrate 506 and a first alignment layer 514. A seal 516 and a spacer 518 are provided between the first alignment layer 514 and a second alignment layer 520, which sandwich liquid crystals 522 in between. A common electrode 524 and color matrices 526 are disposed adjacent to a bottom surface of a color filter substrate 528 and between the color filter substrate 528 and the second alignment layer 520. As illustrated in FIG. 5, a top polarizer 530 is disposed adjacent to a top surface of the color filter substrate 528. Advantageously, either, or both, of the electrodes 510 and 524 can be implemented using the surface-embedded structures described herein.

In some embodiments, the surface-embedded structures can be used as common electrodes in color filter plates, which are used in LCDs. FIG. 5B illustrates a color filter 540 for use in an LCD according to an embodiment of the invention. A common electrode 541 is disposed adjacent to an overcoat/protective layer 542, which is deposited adjacent to Red, Green, and Blue (“RGB”) color matrices 543, which is adjacent to a black matrix 544, which are all disposed on a glass substrate 545. The overcoat/protective layer 542 can include, for example, an acryl resin, a polyimide resin, a polyurethane resin, epoxy, or any combination thereof, and can be used to planarize a topography of the RGB color matrices 543 and the black matrix 544. In other embodiments, the overcoat/protective layer 542 can conform to the topology of the RGB color matrices 543 and the black matrix 544. In other embodiments, the overcoat/protective layer 542 can be omitted. In some embodiments, the black matrix 544 can be made to be electrically conductive, and can form electrical contact with the common electrode 541; in such embodiments, the black matrix 544 can be viewed as a busbar for the common electrode 541. Advantageously, the common electrode 541 can be implemented using the surface-embedded structures described herein.

In other embodiments, the surface-embedded structures can be used as electrodes in solar cells. During operation of a solar cell, light is absorbed by a photoactive material to produce charge carriers in the form of electron-hole pairs. Electrons exit the photoactive material through one electrode, while holes exit the photoactive material through another electrode. The net effect is a flow of an electric current through the solar cell driven by incident light, which electric current can be delivered to an external load to perform useful work. The TCE of the solar cell (or display) can be composed of a host material of glass, PMMA, polycarbonate, or PET. Additionally, a thin PMMA-based film can coated on glass, with silver nanowires surface-embedded in the PMMA. Alternatively, a thin silane, siloxane, silicate, or other ceramic precursor can be coated on a PMMA substrate, with silver nanowires surface-embedded in the thin silane-based coating. This composition of a glass-based coating on a plastic offers benefits of enhanced robustness, scratch-resistance, flexibility, facile processability, low weight, higher toughness, resilience, crack resistance, low cost, and so forth, compared to a pure glass host material for the silver nanowires. In another embodiment, an embedded TCE composed of any host material can also feature one or more antireflective coatings or surface modifications to enhance the transparency or reduce reflection on one or more interfaces of the material.

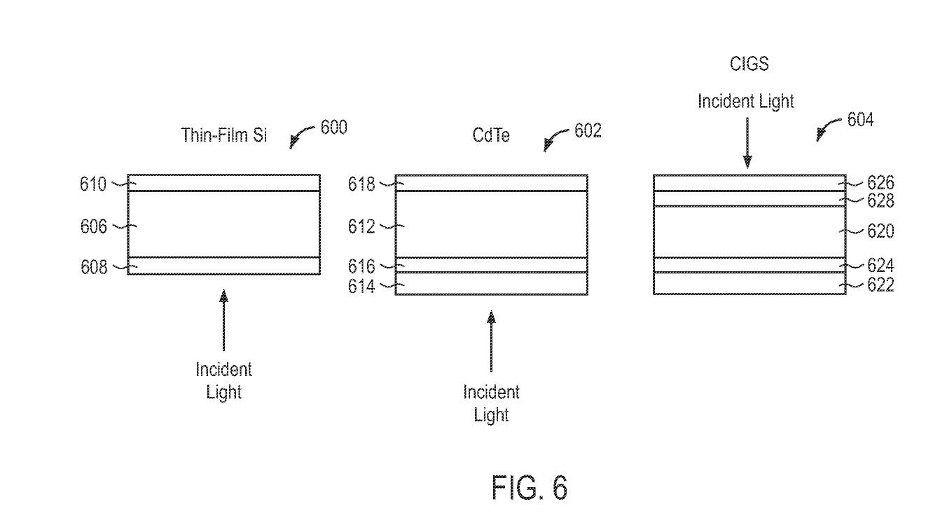

FIG. 6 illustrates thin-film solar cells 600, 602, and 604 according to an embodiment of the invention. In particular, the thin-film solar cell 600 corresponds to a thin-film silicon solar cell, in which a photoactive layer 606 formed of silicon is disposed between a TCE 608 and a back electrode 610. Referring to FIG. 6, the thin-film solar cell 602 corresponds to a CdTe solar cell, in which a photoactive layer 612 formed of CdTe is disposed between a TCE 614 and a back electrode 618, and a barrier layer 616 is disposed between the photoactive layer 612 and the TCE 614. And, the thin-film solar cell 604 corresponds to a CIGS solar cell, in which a photoactive layer 620 formed of CIGS is disposed between a TCE 626 and a back electrode 624, and a barrier layer 628 is disposed between the photoactive layer 620 and the TCE 626. The various layers of the thin-film solar cell 604 are disposed on top of a substrate 622, which can be rigid. Advantageously, the TCEs 608, 614, and 626 can be implemented using the surface-embedded structures described herein, such as those shown in FIG. 2C and FIG. 2G. It is also contemplated that the back electrodes 610, 618, and 624 can be implemented using the surface-embedded structures. It is further contemplated that TCEs implemented using the surface embedded-structures can be used in crystalline, polycrystalline, single crystalline, or amorphous silicon solar cells. It is further contemplated that by, using the TCEs implemented using the surface embedded-structures discussed herein, fewer, thinner, more widely spaced, busbars, or a combination thereof, can be used, which can increase the performance of a solar cell by, for instance, decreasing the amount of light blocked by the busbars. In another embodiment, the surface-embedded structures described herein, can be used to help boost the performance of a solar cell by, for instance, increasing the amount of light available to the solar cell, increasing absorption of light into the solar cell, or a combination thereof.

In other embodiments, the surface-embedded structures can be used as electrodes in touch screen devices. A touch screen device is typically implemented as an interactive input device integrated with a display, which allows a user to provide inputs by contacting a touch screen. The touch screen is typically transparent to allow light and images to transmit through.

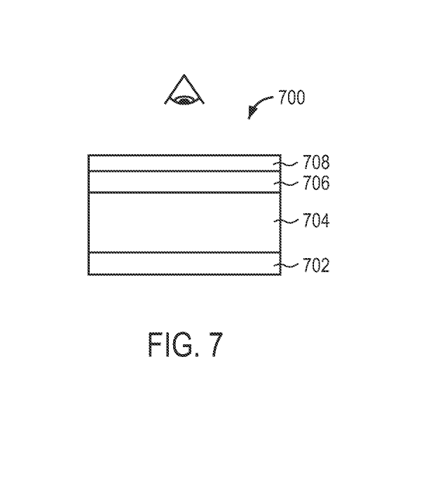

FIG. 7 illustrates a projected capacitive touch screen device 700 according to an embodiment of the invention. The touch screen device 700 includes a thin-film separator 704 that is disposed between a pair of TCEs 702 and 706, as well as a rigid touch screen 708 that is disposed adjacent to a top surface of the TCE 708. A change in capacitance occurs when a user contacts the touch screen 708, and a controller (not illustrated) senses the change and resolves a coordinate of the user contact. Advantageously, either, or both, of the TCEs 702 and 706 can be implemented using the surface-embedded structures described herein, such as that shown in FIG. 1H. It is also contemplated that the surface-embedded structures can be included in resistive touch screen devices (e.g., 4-wire, 5-wire, and 8-wire resistive touch screen devices), which include a flexible touch screen and operate based on electrical contact between a pair of TCEs when a user presses the flexible touch screen.

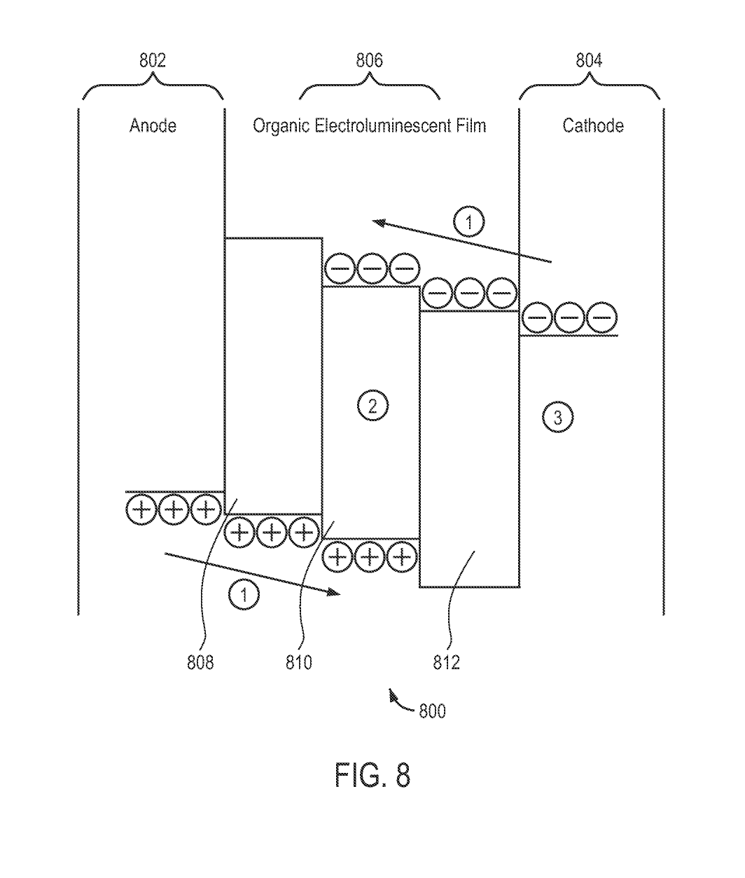

In other embodiments, the surface-embedded structures can be used as electrodes in solid-state lighting devices. FIG. 8 illustrates an OLED lighting device 800 according to an embodiment of the invention. The OLED device 800 includes an organic electroluminescent film 806, which includes a Hole Transport Layer (“HTL”) 808, an Emissive Layer (“EML”) 810, and an Electron Transport Layer (“ETL”) 812. Two electrodes, namely an anode 802 and a cathode 804, are disposed on either side of the film 806. When a voltage is applied to the electrodes 802 and 804, electrons (from the cathode D04) and holes (from the anode D02) pass into the film 806 (stage 1). The electrons and holes recombine in the presence of light-emitting molecules within the EML 810 (stage 2), and light is emitted (stage 3) and exits through the cathode 804. Advantageously, either, or both, of the electrodes 802 and 804 can be implemented using the surface-embedded structures described herein. It is also contemplated that the surface-embedded structures can be included in OLED displays, which can be implemented in a similar fashion as illustrated in FIG. 8.

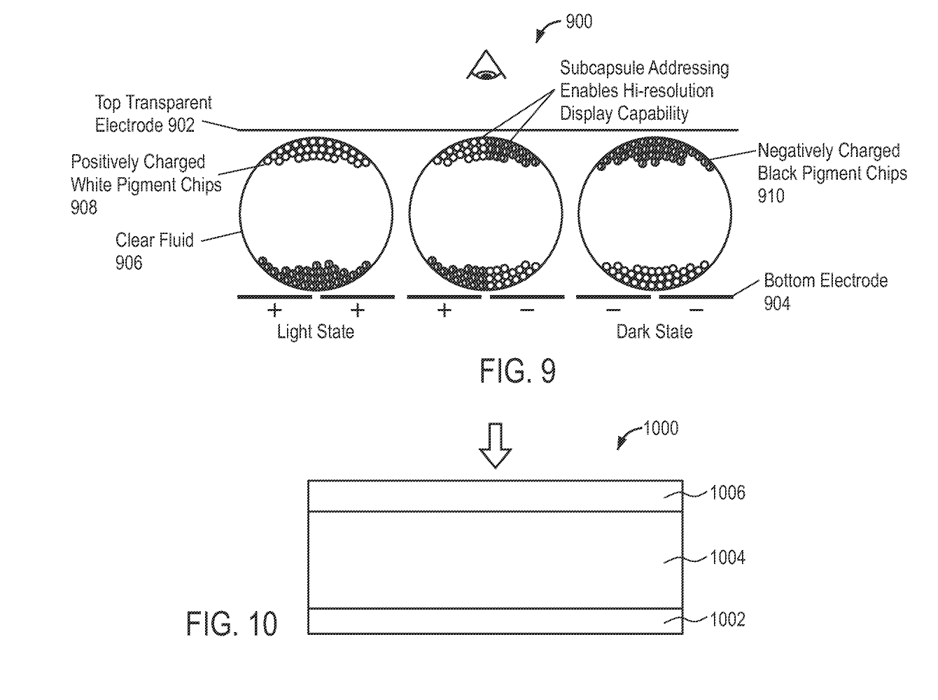

In other embodiments, the surface-embedded structures can be used as electrodes in e-paper. FIG. 9 illustrates an e-paper 900 according to an embodiment of the invention. The e-paper 900 includes a TCE 902 and a bottom electrode 904, between which are positively charged white pigments 908 and negatively charged black pigments 910 dispersed in a carrier medium 906. When a “negative” electric field is applied, the black pigments 910 move towards the bottom electrode 904, while the white pigments 908 move towards the top transparent conductive electrode 902, thereby rendering that portion of the e-paper 900 to appear white. When the electric field is reversed, the black pigments 910 move towards the top transparent conductive electrode 902, thereby rendering that portion of the e-paper 900 to appear dark. Advantageously, either, or both, of the electrodes 902 and 904 can be implemented using the surface-embedded structures described herein.

In still further embodiments, the surface-embedded structures can be used as electrodes in smart windows. FIG. 10 illustrates a smart window 1000 according to an embodiment of the invention. The smart window 1000 includes a pair of TCEs 1002 and 1006, between which is an active layer 1004 that controls passage of light through the smart window 1000. In the illustrated embodiment, the active layer 1004 includes liquid crystals, although the active layer 1004 also can be implemented using suspended particles or electrochromic materials. When an electric field is applied, the liquid crystals respond by aligning with respect to the electric field, thereby allowing the passage of light. When the electrical field is absent, the liquid crystals become randomly oriented, thereby inhibiting the passage of light. In such manner, the smart window 1000 can appear transparent or translucent. Advantageously, either, or both, of the electrodes 1002 and 1006 can be implemented using the conductive structures described herein. Additionally, it is contemplated that the increased smoothness of a TCE implemented using the surface-embedded structures described herein (e.g., due to the localization of additives into a “planar” embedding region) can decrease a haze compared to other conventional structures.

### Manufacturing Methods of Surface-Embedded Structures

Disclosed herein are manufacturing methods to form surface-embedded structures in a highly-scalable, rapid, and low-cost fashion, in which additives are durably and surface-embedded into a wide variety of host materials, securely burrowing the additives into the host materials.

Some embodiments of the manufacturing methods can be generally classified into two categories: (1) surface-embedding additives into a dry composition to yield a host material with the surface-embedded additives; and (2) surface-embedding additives into a wet composition to yield a host material with the surface-embedded additives. It will be understood that such classification is for ease of presentation, and that “dry” and “wet” can be viewed as relative terms (e.g., with varying degrees of dryness or wetness), and that the manufacturing methods can apply to a continuum spanned between fully “dry” and fully “wet.” Accordingly, processing conditions and materials described with respect to one category (e.g., dry composition) can also apply with respect to another category (e.g., wet composition), and vice versa. It will also be understood that hybrids or combinations of the two categories are contemplated, such as where a wet composition is dried or otherwise converted into a dry composition, followed by surface-embedding of additives into the dry composition to yield a host material with the surface-embedded additives. It will further be understood that, although “dry” and “wet” sometimes may refer to a level of water content or a level of solvent content, “dry” and “wet” also may refer to another characteristic of a composition in other instances, such as a degree of cross-linking or polymerization.

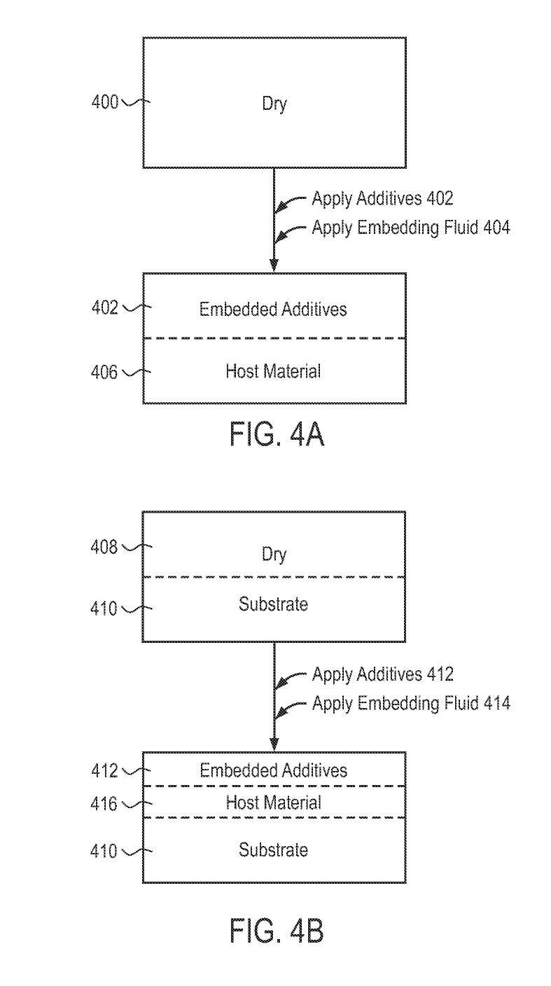

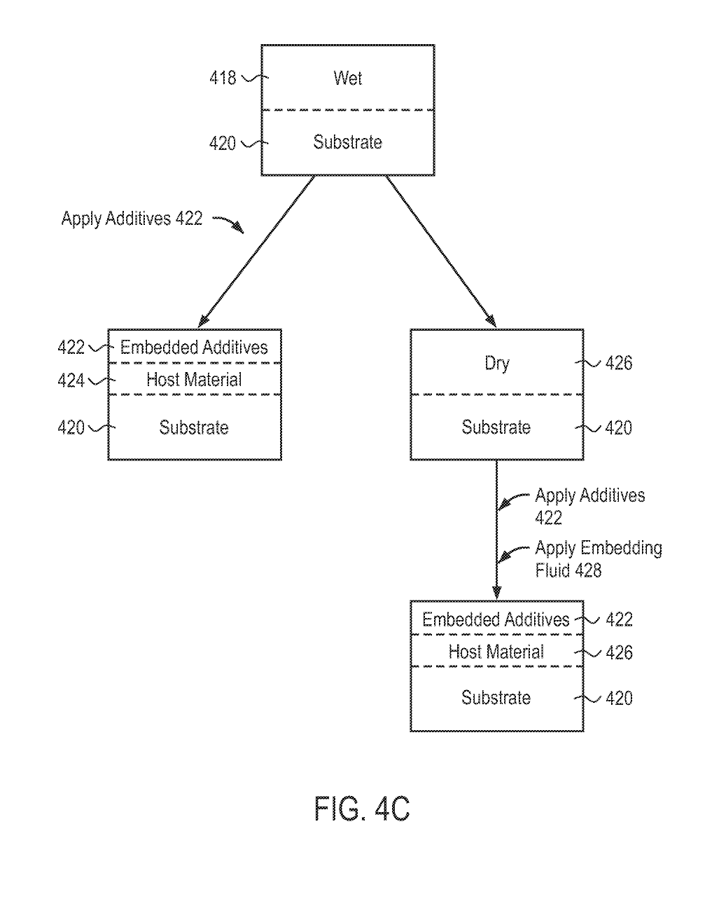

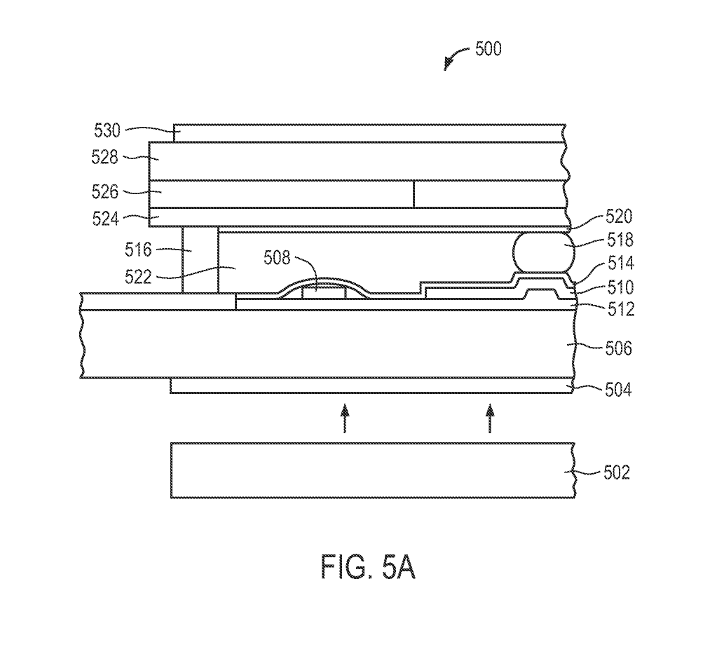

Attention first turns to FIG. 4A and FIG. 4B, which illustrate manufacturing methods for surface-embedding additives into dry compositions, according to embodiments of the invention.

By way of overview, the illustrated embodiments involve the application of an embedding fluid to allow additives to be embedded into a dry composition, such as one including a polymer, a ceramic, a ceramic precursor, or a combination thereof. In general, the embedding fluid serves to reversibly alter the state of the dry composition, such as by dissolving, reacting, softening, solvating, swelling, or any combination thereof, thereby facilitating embedding of the additives into the dry composition. For example, the embedding fluid can be specially formulated to act as an effective solvent for a polymer, while possibly also being modified with stabilizers (e.g., dispersants) to help suspend the additives in the embedding fluid. The embedding fluid also can be specially formulated to reduce or eliminate problems with solvent/polymer interaction, such as hazing, crazing, and blushing. The embedding fluid can include a solvent or a solvent mixture that is optimized to be low-cost, Volatile Organic Compound (“VOC”)-free, VOC-exempt or low-VOC, Hazardous Air Pollutant (“HAP”) free, non-ozone depleting substances (“non-ODS”), low or non-volatile, and low hazard or non-hazardous. As another example, the dry composition can include a ceramic or a ceramic precursor in the form of a gel or a semisolid, and application of the embedding fluid can cause the gel to be swollen by filling pores with the fluid, by elongation of partially uncondensed oligomeric or polymeric chains, or both. As a further example, the dry composition can include a ceramic or a ceramic precursor in the form of an ionic polymer, such as sodium silicate or another alkali metal silicate, and application of the embedding fluid can dissolve at least a portion of the ionic polymer to allow embedding of the additives. The embedding of the additives is then followed by hardening or other change in state of the softened or swelled composition, resulting in a host material having the additives embedded therein. For example, the softened or swelled composition can be hardened by exposure to ambient conditions, or by cooling the softened or swelled composition. In other embodiments, the softened or swelled composition is hardened by evaporating or otherwise removing at least a portion of the embedding fluid (or other liquid or liquid phase that is present), applying airflow, applying a vacuum, or any combination thereof. In the case of a ceramic precursor, curing can be carried out after embedding such that the ceramic precursor is converted into a glass. Curing can be omitted, depending on the particular application. Depending on the particular ceramic precursor (e.g., a silane), more or less heat can be involved to achieve various degrees of curing or conversion into a fully reacted or fully formed glass.

The mechanism of action of surface-embedding can be broken down into stages, as an aid for conceptualization and for ease of presentation. However, these stages can be combined or can occur substantially simultaneously. These stages include: (a) the embedding fluid interacting with a surface (here, for example, a surface of a polymer), (b) the additives penetrating the surface, and (c) the embedding fluid leaving the surface.

In stage (a) and as the embedding fluid impacts the surface, polymer chains of the dry composition disentangle and extend up and above the surface and occupy a larger volume due to a combination of swelling and solvation, which loosen the polymer chains. The zone of swollen polymer extends above and below the original surface of the dry composition. This effect occurs over the span of a few seconds or less, which is surprisingly quick given that typical solvent/polymer dissolution procedures are carried out in terms of hours and days. The surface of the polymer has a higher concentration of low molecular weight chains, chain ends, and high surface energy functionality compared to the bulk, which can increase the rate of swelling or solubilizing at the surface.

In stage (b) and once the polymer surface has been swollen, additives are applied into this zone between the polymer chains by the momentum of the embedding fluid and the additives (or by other application of velocity to the additives or the embedding fluid) and by diffusion/mixing processes as the embedding fluid impacts the surface. In some embodiments, embedding can be achieved without the momentum of the embedding fluid and the additives. Another factor that can affect this swelling/dispersion process is the impact energy—if the additives impact the surface, the additives' momentum transfer in a highly localized area can impart energy input into the surface, which can heat the surface to increases solubility of the polymer, thereby facilitating the secure embedding, surface-impregnation, or partial sinking of the additives into the polymer.

In stage (c) and as the embedding fluid evaporates or is otherwise removed, the polymer chains re-form with one another and around the additives. The polymer chains that had extended above and beyond the original surface can capture and adsorb the additives, and pull them into the surface, rendering them securely and durably embedded therein. The structural perturbations due to the embedded particles can be relatively small, and the resulting host material and its enveloped additives can substantially retain their original optical transparency and surface morphology.

Referring to FIG. 4A, a dry composition 400 is provided in the form of a substrate. The dry composition 400 can correspond to a host material and, in particular, can include any material previously listed as suitable host materials, such as a polymer, a ceramic, or any combination thereof. It is also contemplated that the dry composition 400 can correspond to a host material precursor, which can be converted into the host material by suitable processing, such as drying, curing, cross-linking, polymerizing, or any combination thereof. In some embodiments, the dry composition 400 can include a material with a solid phase as well as a liquid phase, or can include a material that is at least partially solid or has properties resembling those of a solid, such as a semisolid, a gel, and the like. Next, and referring to FIG. 4A, additives 402 and an embedding fluid 404 are applied to the dry composition 400. The additives 402 can be in solution or otherwise dispersed in the embedding fluid 404, and can be simultaneously applied to the dry composition 400 via one-step embedding. Alternatively, the additives 402 can be separately applied to the dry composition 400 before, during, or after the embedding fluid 404 treats the dry composition 400. The separate application of the additives 402 can be referred as two-step embedding. Subsequently, the resulting host material 406 has at least some of the additives 402 partially or fully embedded into a surface of the host material 406. Optionally, suitable processing can be carried out to convert the softened or swelled composition 400 into the host material 406.

FIG. 4B is process flow similar to FIG. 4A, but with a dry composition 408 provided in the form of a coating that is disposed on top of a substrate 410. The dry composition 408 can correspond to a host material, or can correspond to a host material precursor, which can be converted into the host material by suitable processing, such as drying, curing, cross-linking, polymerizing, or any combination thereof. Other characteristics of the dry composition 408 can be similar to those described above with reference to FIG. 4A, and are not repeated below. Referring to FIG. 4B, the substrate can be transparent or opaque, can be flexible or rigid, and can be composed of, for example, PE, PET, PETG, polycarbonate, PVC, PP, acrylic-based polymer, ABS, ceramic, glass, or any combination thereof, as well as any other material previously listed as suitable host materials. Next, additives 412 and an embedding fluid 414 are applied to the dry composition 408. The additives 412 can be in solution or otherwise dispersed in the embedding fluid 414, and can be simultaneously applied to the dry composition 408 via one-step embedding. Alternatively, the additives 412 can be separately applied to the dry composition 408 before, during, or after the embedding fluid 414 treats the dry composition 408. As noted above, the separate application of the additives 412 can be referred as two-step embedding. Subsequently, the resulting host material 416 (which is disposed on top of the substrate 410) has at least some of the additives 412 partially or fully embedded into a surface of the host material 416. Optionally, suitable processing can be carried out to convert the softened or swelled composition 408 into the host material 416.

In some embodiments, additives are dispersed in an embedding fluid, or dispersed in a separate carrier fluid and separately applied to a dry composition. Dispersion can be accomplished by mixing, sonicating, shaking, vibrating, flowing, chemically modifying the additives' surfaces, chemically modifying a fluid, adding a dispersing or suspending agent to the fluid, or otherwise processing the additives to achieve the desired dispersion. The dispersion can be uniform or non-uniform. A carrier fluid can serve as an embedding fluid (e.g., an additional embedding fluid), or can have similar characteristics as an embedding fluid. In other embodiments, a carrier fluid can serve as a transport medium to carry or convey additives, but is otherwise substantially inert towards the additives and the dry composition.

Fluids (e.g., embedding fluids and carrier fluids) can include liquids, gases, or supercritical fluids. Combinations of different types of fluids are also suitable. Fluids can include one or more solvents. For example, a fluid can include water, an ionic or ion-containing solution, an organic solvent (e.g., a polar, organic solvent; a non-polar, organic solvent; an aprotic solvent; a protic solvent; a polar aprotic solvent, or a polar, protic solvent); an inorganic solvent, or any combination thereof. Oils also can be considered suitable fluids. Salts, surfactants, dispersants, stabilizers, or binders can also be included in the fluids.

Examples of suitable organic solvents include 2-methyltetrahydrofuran, a chloro-hydrocarbon, a fluoro-hydrocarbon, a ketone, a paraffin, acetaldehyde, acetic acid, acetic anhydride, acetone, acetonitrile, an alkyne, an olefin, aniline, benzene, benzonitrile, benzyl alcohol, benzyl ether, butanol, butanone, butyl acetate, butyl ether, butyl formate, butyraldehyde, butyric acid, butyronitrile, carbon disulfide, carbon tetrachloride, chlorobenzene, chlorobutane, chloroform, cycloaliphatic hydrocarbons, cyclohexane, cyclohexanol, cyclohexanone, cyclopentanone, cyclopentyl methyl ether, diacetone alcohol, dichloroethane, dichloromethane, diethyl carbonate, diethyl ether, diethylene glycol, diglyme, di-isopropylamine, dimethoxyethane, dimethyl formamide, dimethyl sulfoxide, dimethylamine, dimethylbutane, dimethylether, dimethylformamide, dimethylpentane, dimethylsulfoxide, dioxane, dodecafluoro-1-hepatanol, ethanol, ethyl acetate, ethyl ether, ethyl formate, ethyl propionate, ethylene dichloride, ethylene glycol, formamide, formic acid, glycerine, heptane, hexafluoroisopropanol, hexamethylphosphoramide, hexamethylphosphorous triamide, hexane, hexanone, hydrogen peroxide, hypochlorite, i-butyl acetate, i-butyl alcohol, i-butyl formate, i-butylamine, i-octane, i-propyl acetate, i-propyl ether, isopropanol, isopropylamine, ketone peroxide, methanol and calcium chloride solution, methanol, methoxyethanol, methyl acetate, methyl ethyl ketone (or MEK), methyl formate, methyl n-butyrate, methyl n-propyl ketone, methyl t-butyl ether, methylene chloride, methylene, methylhexane, methylpentane, mineral oil, m-xylene, n-butanol, n-decane, n-hexane, nitrobenzene, nitroethane, nitromethane, nitropropane, 2-N-methyl-2-pyrrolidinone, n-propanol, octafluoro-1-pentanol, octane, pentane, pentanone, petroleum ether, phenol, propanol, propionaldehyde, propionic acid, propionitrile, propyl acetate, propyl ether, propyl formate, propylamine, p-xylene, pyridine, pyrrolidine, t-butanol, t-butyl alcohol, t-butyl methyl ether, tetrachloroethane, tetrafluoropropanol, tetrahydrofuran, tetrahydronaphthalene, toluene, triethyl amine, trifluoroacetic acid, trifluoroethanol, trifluoropropanol, trimethylbutane, trimethylhexane, trimethylpentane, valeronitrile, xylene, xylenol, or any combination thereof.

Suitable inorganic solvents include, for example, water, ammonia, sodium hydroxide, sulfur dioxide, sulfuryl chloride, sulfuryl chloride fluoride, phosphoryl chloride, phosphorus tribromide, dinitrogen tetroxide, antimony trichloride, bromine pentafluoride, hydrogen fluoride, or any combination thereof.

Suitable ionic solutions include, for example, choline chloride, urea, malonic acid, phenol, glycerol, 1-alkyl-3-methylimidazolium, 1-alkylpyridinium, N-methyl-N-alkylpyrrolidinium, 1-butyl-3-methylimidazolium hexafluorophosphate, ammonium, choline, imidazolium, phosphonium, pyrazolium, pyridinium, pyrrolidnium, sulfonium, 1-ethyl-1-methylpiperidinium methyl carbonate, 4-ethyl-4-methylmorpholinium methyl carbonate, or any combination thereof. Other methylimidazolium solutions can be considered suitable, including 1-ethyl-3-methylimidazolium acetate, 1-butyl-3-methylimidazolium tetrafluoroborate, 1-n-butyl-3-methylimidazolium tetrafluoroborate, 1-butyl-3-methylimidazolium hexafluorophosphate, 1-n-butyl-3-methylimidazolium hexafluorophosphate, 1-butyl-3-methylimidazolium 1,1,1-trifluoro-N—[(trifluoromethyl)sulfonyl]methanesulfonamide, 1-butyl-3-methylimidazolium bis(trifluoro methylsulfonyl)imide, 1-butyl-3-methylimidazolium bis[(trifluoromethyl)sulfonyl]amide, and 1-butyl-3-methylimidazolium bis[(trifluoromethyl)sulfonyl]imide, or any combination thereof.

Other suitable fluids include halogenated compounds, imides, and amides, such as N-ethyl-N,N-bis(1-methylethyl)-1-heptanaminium bis[(trifluoromethyl)sulfonyl]imide, ethyl heptyl-di-(1-methylethyl)ammonium 1,1,1-trifluoro-N-[(trifluoromethyl)sulfonyl]methane sulfonamide, ethylheptyl-di-(1-methyl ethyl)ammonium bis(trifluoromethylsulfonyl)imide, ethylheptyl-di-(1-methylethyl)ammonium bis[(trifluoromethyl)sulfonyl]amide, or any combination thereof. A fluid can also include ethylheptyl-di-(1-methylethyl)ammonium bis[(trifluoromethyl)sulfonyl]imide, N₅N₅N— tributyl-1-octanaminium trifluoromethanesulfonate, tributyloctylammonium triflate, tributyloctylammonium trifluoromethanesulfonate, N,N,N-tributyl-1-hexanaminium bis[(trifluoromethyl)sulfonyl]imide, tributylhexylammonium 1,1,1-trifluoro-N-[(trifluoromethyl)sulfonyl]methanesulfonamide, tributylhexylammonium bis(trifluoromethylsulfonyl)imide, tributylhexylammonium bis[(trifluoromethyl)sulfonyl]amide, tributylhexylammonium bis[(trifluoromethyl)sulfonyl]imide, N,N,N-tributyl-1-heptanaminium bis[(trifluoromethyl)sulfonyl]imide, tributylheptylammonium 1,1,1-trifluoro-N-[(trifluoro methyl)sulfonyl]methanesulfonamide, tributylheptylammonium bis(trifluoromethylsulfonyl)imide; tributylheptylammonium bis[(trifluoromethyl)sulfonyl]amide, tributylheptylammonium bis[(trifluoromethyl)sulfonyl]imide, N,N,N-tributyl-1-octanaminium bis[(trifluoromethyl)sulfonyl]imide, tributyloctylammonium 1,1,1-trifluoro-N-[(trifluoromethyl)sulfonyl]methane sulfonamide, tributyloctylammonium bis(trifluoromethylsulfonyl)imide, tributyloctylammonium bis[(trifluoromethyl)sulfonyl]amide, tributyloctylammonium bis[(trifluoromethyl)sulfonyl]imide, 1-butyl-3-methylimidazolium trifluoroacetate, 1-methyl-1-propylpyrrolidinium 1,1,1-trifluoro-N-[(trifluoromethyl)sulfonyl]methanesulfonamide, 1-methyl-1-propylpyrrolidinium bis(trifluoro methylsulfonyl)imide, 1-methyl-1-propylpyrrolidinium bis[(trifluoromethyl)sulfonyl]amide, 1-methyl-1-propylpyrrolidinium bis[(trifluoromethyl)sulfonyl]imide, 1-butyl-1-methyl pyrrolidinium 1,1,1-trifluoro-N-[(trifluoromethyl)sulfonyl]methanesulfonamide, 1-butyl-1-methylpyrrolidinium bis(trifluoromethylsulfonyl)imide, 1-butyl-1-methylpyrrolidinium bis [(trifluoromethyl)sulfonyl]amide, 1-butyl-1-methylpyrrolidinium bis[(trifluoromethyl)sulfonyl]imide, 1-butylpyridinium 1,1,1-trifluoro-N-[(trifluoromethyl)sulfonyl]methanesulfonamide, 1-butylpyridinium bis(trifluoromethylsulfonyl)imide, 1-butylpyridinium bis[(trifluoromethyl)sulfonyl]amide, 1-butylpyridinium bis[(trifluoromethyl)sulfonyl]imide, 1-butyl-3-methyl imidazolium bis(perfluoroethylsulfonyl)imide, butyltrimethylammonium bis(trifluoromethyl sulfonyl)imide, 1-octyl-3-methylimidazolium 1,1,1-trifluoro-N-[(trifluoromethyl)sulfonyl]methanesulfonamide, 1-octyl-3-methylimidazolium bis(trifluoromethylsulfonyl)imide, 1-octyl-3-methylimidazolium bis[(trifluoromethyl)sulfonyl]amide, 1-octyl-3-methylimidazolium bis[(trifluoromethyl)sulfonyl]imide, 1-ethyl-3-methylimidazolium tetrafluoroborate, N₅N₅N-trimethyl-1-hexanaminium bis[(trifluoromethyl)sulfonyl]imide, hexyltrimethylammonium 1,1,1-trifluoro-N-[(trifluoromethyl)sulfonyl]methane sulfonamide, hexyltrimethylammonium bis(trifluoromethylsulfonyl)imide, hexyltrimethylammonium bis[(trifluoromethyl)sulfonyl]amide, hexyltrimethylammonium bis[(trifluoromethyl)sulfonyl]imide, N,N,N-trimethyl-1-heptanaminium bis[(trifluoromethyl)sulfonyl]imide, heptyltrimethylammonium 1,1,1-trifluoro-N—[(trifluoromethyl)sulfonyl]methanesulfonamide, heptyltrimethylammonium bis(trifluoro methylsulfonyl)imide, heptyltrimethylammonium bis[(trifluoromethyl)sulfonyl]amide, heptyltrimethylammonium bis[(trifluoromethyl)sulfonyl]imide, N,N,N-trimethyl-1-octanaminium bis[(trifluoromethyl)sulfonyl]imide, trimethyloctylammonium 1,1,1-trifluoro-N-[(trifluoro methyl)sulfonyl]methanesulfonamide, trimethyloctylammonium bis(trifluoromethylsulfonyl)imide, trimethyloctylammonium bis[(trifluoromethyl)sulfonyl]amide, trimethyloctylammonium bis[(trifluoromethyl)sulfonyl]imide, 1-ethyl-3-methylimidazolium ethyl sulfate, or any combination thereof.

Control over surface-embedding of additives can be achieved through the proper balancing of the swelling-dispersion-evaporation-application stages. This balance can controlled by, for example, a solvent-host material interaction parameter, sizes of additives, reactivity and volatility of an embedding fluid, impinging additive momentum or velocity, temperature, humidity, pressure, and others factors. More particularly, relevant processing parameters for surface-embedding are listed below for some embodiments of the invention:

Embedding Fluid Selection:
Compatibility of embedding fluid with surface (e.g., matching or comparison of Hildebrand and Hansen solubility parameters, dielectric constant, partition coefficient, pKa, etc.)
Evaporation rate, boiling point, vapor pressure, enthalpy of vaporization of embedding fluid
Diffusion of embedding fluid into surface: thermodynamic and kinetics considerations
Viscosity of embedding fluid
Surface tension of embedding fluid, wicking, and capillary effects
Azeotroping, miscibility, and other interactions with other fluids

Application Conditions:
Duration of fluid-surface exposure
Temperature
Humidity
Application method (e.g., spraying, printing, rolling coating, gravure coating, slot-die, cup coating, blade coating, airbrushing, immersion, dip coating, etc.)
Impact/momentum/velocity of additives onto surface (e.g., may influence depth or extent of embedding)
Post-processing conditions (e.g., heating, evaporation, fluid removal, air-drying, etc.)

Host Material:
Surface energy
Roughness and surface area
Pre-treatments (e.g., ultraviolet ozonation, base etch, cleaning, solvent priming, etc.)
Dispersion/suspension of additives in fluid prior to embedding (e.g., additives can remain dispersed in solution through physical agitation, chemical/capping stabilization, steric stabilization, or are inherently solubilized)
Mitigation of undesired effects (e.g., hazing, crazing, blushing, irreversible destruction of host material, uneven wetting, roughness, etc.)

Some, or all, of the aforementioned parameters can be altered or selected to tune a depth of embedding of additives into a given host material. For example, higher degrees of embedding deep into a surface of a host material can be achieved by increasing a solvency power of an embedding fluid interacting with the host material, matching closely Hansen solubility parameters of the embedding fluid-substrate, prolonging the exposure duration of the embedding fluid in contact with the host material, increasing an amount of the embedding fluid in contact with the host material, elevating a temperature of the system, increasing a momentum of additives impinging onto the host material, increasing a diffusion of either, or both, of the embedding fluid and the additives into the host material, or any combination thereof.

The following Table 1 provides examples of some embedding fluids suitable for embedding additives into dry compositions composed of particular polymers, according to an embodiment of the invention. Using the processing parameters set forth above, it will be understood that other embedding fluids can be selected for these particular polymers, as well as other types of polymers, ceramics, and ceramic precursors.

TABLE 1

| Polymer | Embedding Fluids |
|---|---|
| Acrylonitrile | acetone, dichloromethane, dichloromethane/mineral spirits 80/20 vol %, |
| butadiene styrene | methyl acetate, methylethylketone, tetrahydrofuran, ethyl lactate, |
| (or ABS) | cyclohexanone, toluene, tetrafluoropropanol, trifluoroethanol, |
| | hexafluoroisopropanol, or any combination thereof |
| Polycarbonate | cyclohexanone, dichloromethane, 60 vol % methyl acetate/20 vol % ethyl |
| | acetate/20 vol % cyclohexanone, tetrahydrofuran, toluene, |
| | tetrafluoropropanol, trifluoroethanol, hexafluoroisopropanol, |
| | methylethylketone, acetone, other pure ketones, or any combination |
| | thereof |
| Acrylic- | dichloromethane, methylethylketone, tetrafluoropropanol, |
| polyacrylate, | trifluoroethanol, hexafluoroisopropanol, terpineol, 1-butanol, |
| polymethyl | isopropanol, tetrahydrofuran, terpineol, trifluoroethanol/isopropanol, |
| methacrylate | other fluorinated alcohols, or any combination thereof |
| (or PMMA) | |
| Polystyrene | acetone, dichloromethane, tetrahydrofuran, toluene, 50 vol % acetone/50 |
| | vol % tetrahydrofuran, or any combination thereof |
| Polyvinyl chloride | tetrahydrofuran, 50% acetone/50% tetrahydrofuran, or any combination |
| (or PVC) | thereof |

Fluids (e.g., embedding fluids and carrier fluids) can also include salts, surfactants, stabilizers, and other agents useful in conferring a particular set of characteristics on the fluids. Stabilizers can be included based on their ability to at least partially inhibit inter-additive agglomeration. Other stabilizers can be chosen based on their ability to preserve the functionality of additives. Other agents can be used to adjust rheological properties, evaporation rate, and other characteristics.

Fluids and additives can be applied so as to be largely stationary relative to a surface of a dry composition. In other embodiments, application is carried out with relative movement, such as by spraying a fluid onto a surface, by conveying a dry composition through a falling curtain of a fluid, or by conveying a dry composition through a pool or bath of a fluid. Application of fluids and additives can be effected by airbrushing, atomizing, nebulizing, spraying, electrostatic spraying, pouring, rolling, curtaining, wiping, spin casting, dripping, dipping, painting, flowing, brushing, immersing, patterning (e.g., stamping, inkjet printing, controlled spraying, controlled ultrasonic spraying, and so forth), flow coating methods (e.g., slot die, capillary coating, meyer rod, cup coating, draw down, and the like), or any combination thereof. In some embodiments, additives are propelled, such as by a sprayer, onto a surface, thereby facilitating embedding by impact with the surface. In other embodiments, a gradient is applied to a fluid, additives, or both. Suitable gradients include magnetic and electric fields. The gradient can be used to apply, disperse, or propel the fluid, additives, or both, onto a surface. In some embodiments, the gradient is used to manipulate additives so as to control the extent of embedding. An applied gradient can be constant or variable. Gradients can be applied before a dry composition is softened or swelled, while the dry composition remains softened or swelled, or after the dry composition is softened or swelled. It is contemplated that a dry composition can be heated to achieve softening, and that either, or both, of a fluid and additives can be heated to promote embedding.

Application of fluids and additives and embedding of the additives can be spatially controlled to yield patterns. In some embodiments, spatial control can be achieved with a physical mask, which can be placed between an applicator and a surface to block a segment of applied additives from contacting the surface, resulting in controlled patterning of additive embedding. In other embodiments, spatial control can be achieved with a photomask. A positive or negative photomask can be placed between a light source and a surface, which can correspond to a photoresist. Light transmitted through non-opaque parts of the photomask can selectively affect a solubility of exposed parts of the photoresist, and resulting spatially controlled soluble regions of the photoresist can permit controlled embedding of additives. In other embodiments, spatial control can be achieved through the use of electric gradients, magnetic gradients, electromagnetic fields, thermal gradients, pressure or mechanical gradients, surface energy gradients (e.g., liquid-solid-gas interfaces, adhesion-cohesion forces, and capillary effects), or any combination thereof. Application of an overlying coating (e.g., the coatings 214 and 250 illustrated in FIG. 2C and FIG. 2G, respectively) can be carried out in a similar fashion. For example, in the case ITO or another transparent metal oxide, an electrically conductive material can be sputtered onto a composition with surface-exposed, surface-embedded additives. In the case of an electrically conductive polymer, a carbon-based coating, and other types of coatings, an electrically conductive material can be applied by coating, spraying, flow coating, and so forth.

As noted above, additives can be dispersed in an embedding fluid, and applied to a dry composition along with the embedding fluid via one-step embedding. Additives also can be applied to a dry composition separately from an embedding fluid via two-step embedding. In the latter scenario, the additives can be applied in a wet form, such as by dispersing in a carrier fluid or by dispersing in the same embedding fluid or a different embedding fluid. Still in the latter scenario, the additives can be applied in a dry form, such as in the form of aerosolized powder. It is also contemplated that the additives can be applied in a quasi-dry form, such as by dispersing the additives in a carrier fluid that is volatile, such as methanol, another low boiling point alcohol, or another low boiling point organic solvent, which substantially vaporizes prior to impact with a dry composition.

By way of example, one embodiment involves spraying, airbrushing, or otherwise atomizing a solution of nanowires or other electrically conductive additives dispersed in an appropriate carrier fluid onto a dry composition.

As another example, one embodiment involves pre-treating a dry composition by spraying or otherwise contacting an embedding fluid with the dry composition, and then, after the passage of time t₁, spraying or airbrushing nanowires or other electrically conductive additives with velocity such that the combination of the temporarily softened dry composition and the velocity of the impinging nanowires allow rapid and durable surface-embedding of the nanowires. t₁ can be, for example, in the range of about 0 nanosecond to about 24 hours, such as from about 1 nanosecond to about 24 hours, from about 1 nanosecond to about 1 hour or from about 1 second to about 1 hour. Two spray nozzles can be simultaneously or sequentially activated, with one nozzle dispensing the embedding fluid, and the other nozzle dispensing, with velocity, atomized nanowires dispersed in a carrier fluid towards the dry composition. Air-curing or higher temperature annealing optionally can be included.

As another example, one embodiment involves spraying, airbrushing, or otherwise atomizing a solution of nanowires or other electrically conductive additives dispersed in a carrier fluid onto a dry composition. After the passage of time t₂, a second spraying, airbrushing, or atomizing operation is used to apply an embedding fluid so as to permit efficient surface-embedding of the nanowires. t₂ can be, for example, in the range of about 0 nanosecond to about 24 hours, such as from about 1 nanosecond to about 24 hours, from about 1 nanosecond to about 1 hour or from about 1 second to about 1 hour. Two spray nozzles can be simultaneously or sequentially activated, with one nozzle dispensing the embedding fluid, and the other nozzle dispensing, with velocity, atomized nanowires dispersed in the carrier fluid towards the dry composition. Air-curing or higher temperature annealing optionally can be included.

As a further example, one embodiment involves applying nanowires or other electrically conductive additives onto a dry composition composed of sodium silicate or another alkali metal silicate or other solid glass. Either simultaneously or as a separate operation, an embedding fluid composed of heated, basic water is applied in liquid or vapor form to the sodium silicate at either room temperature or elevated temperature, which causes the sodium silicate to at least partially dissolve, thereby permitting entry of the nanowires into the dissolved sodium silicate. The water is evaporated or otherwise removed, causing the sodium silicate to re-solidify with the nanowires embedded within the sodium silicate. Air-curing or higher temperature annealing optionally can be included.

Attention next turns to FIG. 4C, which illustrate a manufacturing method for surface-embedding additives 422 into a wet composition 418, according to an embodiment of the invention. Referring to FIG. 4C, the wet composition 418 is applied to a substrate 420 in the form of a coating that is disposed on top of the substrate 420. The wet composition 418 can correspond to a dissolved form of a host material and, in particular, can include a dissolved form of any material previously listed as suitable host materials, such as a polymer, a ceramic, a ceramic precursor, or any combination thereof. It is also contemplated that the wet composition 418 can correspond to a host material precursor, which can be converted into the host material by suitable processing, such as drying, curing, cross-linking, polymerizing, or any combination thereof. For example, the wet coating composition 418 can be a coating that is not fully cured or set, a cross-linkable coating that is not fully cross-linked, which can be subsequently cured or cross-linked using suitable polymerization initiators or cross-linking agents, or a coating of monomers, oligomers, or a combination of monomers and oligomers, which can be subsequently polymerized using suitable polymerization initiators or cross-linking agents. In some embodiments, the wet composition 418 can include a material with a liquid phase as well as a solid phase, or can include a material that is at least partially liquid or has properties resembling those of a liquid, such as a semisolid, a gel, and the like. The substrate 420 can be transparent or opaque, can be flexible or rigid, and can be composed of, for example, PE, PET, PETG, polycarbonate, PVC, PP, acrylic-based polymer, ABS, ceramic, or any combination thereof, as well as any other material previously listed as suitable host materials.

Next, according to the option on the left-side of FIG. 4C, the additives 422 are applied to the wet composition 418 prior to drying or while it remains in a state that permits embedding of the additives 422 within the wet composition 418. In some embodiments, application of the additives 422 is via a flow coating method (e.g., slot die, capillary coating, meyer rod, cup coating, draw down, and the like). Although not illustrated on the left-side, it is contemplated that an embedding fluid can be simultaneously or separately applied to the wet composition 418 to facilitate the embedding of the additives 422. Subsequently, the resulting host material 424 has at least some of the additives 422 partially or fully embedded into a surface of the host material 424. Suitable processing can be carried out to convert the wet composition 418 into the host material 424.

Certain aspects regarding the application of the additives 422 and the embedding of the additives 422 in FIG. 4C can be carried out using similar processing conditions and materials as described above for FIG. 4A and FIG. 4B, and those aspects need not be repeated below. The following provides additional details on embodiments related to ceramics and ceramic precursors.

In some embodiments, additives are embedded into a wet composition in the form of a coating of a liquid ceramic precursor, which includes a solvent and a set of reactive species. The embedding is carried out before the solvent has fully dried, followed by the option of curing or otherwise converting the ceramic precursor to a fully condensed or restructured glass. Examples of ceramic precursor reactive species include spin-on glasses, silanes (e.g., Si(OR)(OR′)(OR″)(R′″), Si(OR)(OR′)(R″)(R′″), and Si(OR)(OR′)(R″)(R′″), where R, R′, R″, and R′ are independently selected from alkyl groups, alkenyl groups, alkynyl groups, and aryl groups), titanium analogues of silanes, cerium analogues of silanes, magnesium analogues of silanes, germanium analogues of silanes, siloxanes (e.g., Si(OR)(OR′)(OR″)(OR′″), where R, R′, R″, and R′″ are independently selected from alkyl groups, alkenyl groups, alkynyl groups, and aryl groups), titanium analogues of siloxanes, cerium analogues of siloxanes, magnesium analogues of siloxanes, germanium analogues of siloxanes, alkali metal silicates (e.g., sodium silicate and potassium silicate), or any combination thereof. As more specific examples, a ceramic precursor reactive species can be a siloxane such as tetramethoxysilane (or TMOS), tetraethoxysilane (or TEOS), tetra(isopropoxy)silane, titanium analogues thereof, cerium analogues thereof, magnesium analogues thereof, germanium analogues thereof, or any combination thereof.

In some embodiments, reactive species are at least partially reacted, prior to embedding of additives. Reaction can be carried out by, for example, hydrolysis in the presence of an acid and a catalyst and followed by condensation, thereby yielding oligomeric or polymeric chains. For example, silanes and siloxanes can undergo partial condensation to yield oligomeric or polymeric chains with Si—O—Si linkages, and at least some side groups corresponding to (OR) or (R).

In some embodiments, a liquid ceramic precursor includes at least two different types of reactive species. The different types of species can react with each other, as exemplified by TEOS, TMOS, tetra(isopropoxy)silane, and can be suitably selected in order to control evaporation rate and pre-cured film morphology. Reactive species with larger side groups, such as isopropoxy in the case of tetra(isopropoxy)silane versus methoxy in the case of TMOS, can yield larger pore sizes when converted into a gel, which larger pore sizes can facilitate swelling in the presence of an embedding fluid. Also, upon hydrolysis, larger side groups can be converted into corresponding alcohols with lower volatility, such as isopropyl alcohol in the case of tetra(isopropoxy)silane versus methanol in the case of TMOS, which can slow the rate of drying. In other embodiments, the different types of species are not likely to react, such as sodium silicate and tetra(isopropoxy)silane. This can afford facile curing properties of a bulk of a matrix formed by drying the silicate, while retaining some amount of delayed condensation to allow embedding of additives.

In some embodiments, reactive species, either prior to reaction or subsequent to reaction, can include some amount of Si—C or Si—C—Si linkages, which can impart toughness, porosity, or other desirable characteristics, such as to allow trapping of a solvent to slow the rate of drying or to promote swelling in the presence of an embedding fluid.

In some embodiments, reactive species, either prior to reaction or subsequent to reaction, can include Si—OR groups, where R is a long chain side group with low volatility to slow the rate of drying of a coating of a liquid ceramic precursor. In other embodiments, reactive species can include Si—R′ groups, where R is a long chain side group with low volatility to slow the rate of drying of a coating of a liquid ceramic precursor. Either, or both, of R and R′ also can have characteristics to interact and retain a solvent, thereby slowing the drying process. For example, R and R′ can have polarity, non-polarity, aliphatic characteristics, or other characteristics that match those of the solvent.

In some embodiments, a solvent included in a liquid ceramic precursor can include water, an alcohol, dimethylformamide, dimethyl sulfoxide, another polar solvent, another non-polar solvent, any other suitable fluid listed above, or any combination thereof. For example, the solvent can be non-polar, and water can be used heterogeneously during hydrolysis, with complete condensation occurring after drying a coating of the ceramic precursor. As another example, a combination of solvents can be selected, such that a major component has high volatility in order to carry, wet, or level reactive species, whereas a minor component has low volatility to delay drying of the coating. It is also contemplated that the reactive species can form a relatively small fraction of a total coating volume to slow drying.

In some embodiments, a liquid ceramic precursor can be applied to a substrate using a wide variety of coating methods, such as a roll-to-roll process, roll coating, gravure coating, slot dye coating, knife coating, and spin coating. For example, the liquid ceramic precursor can be applied by spin coating, and additives can be deposited upon the start of spin coating or after the start of spin coating, but before the resulting coating has dried on a spinner.

In some embodiments, additives can be dispersed in a carrier fluid, and then applied in a wet form to a liquid ceramic precursor. The carrier fluid can include the same solvent (or another solvent having similar characteristics) as a low volatility component of the liquid ceramic precursor in order to reduce or avoid adverse interaction upon impact. It is also contemplated that the carrier fluid can be volatile (e.g., methanol or another low boiling alcohol), which substantially vaporizes prior to impact. Another example of a suitable carrier fluid is water.

In some embodiments, curing can be carried out after embedding such that a liquid ceramic precursor is converted into a glass. For example, curing can involve heating to a temperature in the range of about 400° C. to about 500° C. in nitrogen (optionally containing water vapor (possibly saturated)), heating up to a temperature sufficient to remove residual solvent (e.g., from about 100° C. to about 150° C.), or heating to a temperature in the range of about 800° C. to about 900° C. to form a fully condensed glass. Curing can be omitted, such as in the case of sodium silicate (or another alkali silicate) that can dry under ambient conditions into a robust “clear coat.” In some embodiments, curing can also serve as a sintering/annealing operation for embedded nanowires, or other additives.

Turning back to FIG. 4C and referring to the option on the right-side, the wet composition 418 is initially converted into a dry composition 426 by suitable processing, such as by at least partially drying, curing, cross-linking, polymerization, or any combination thereof. Next, the additives 422 and an embedding fluid 428 are applied to the dry composition 426. The additives 422 can be in solution or otherwise dispersed in the embedding fluid 428, and can be simultaneously applied to the dry composition 426 via one-step embedding. Alternatively, the additives 422 can be separately applied to the dry composition 426 before, during, or after the embedding fluid 428 treats the dry composition 426. As noted above, the separate application of the additives 422 can be referred as two-step embedding. Subsequently, the resulting host material 424 has at least some of the additives 422 partially or fully embedded into the surface of the host material 424. Optionally, suitable processing can be carried out to convert the dry composition 426 into the host material 424, such as by additional drying, curing, cross-linking, polymerization, or any combination thereof. Any, or all, of the manufacturing stages illustrated in FIG. 4C can be carried out in the presence of a vapor environment of a suitable fluid (e.g., an embedding fluid or other suitable fluid) to facilitate the embedding of the additives 422, to slow drying of the wet composition 418, or both.

Certain aspects regarding the application of the additives 422 and the embedding fluid 428 and the embedding of the additives 422 in FIG. 4C can be carried out using similar processing conditions and materials as described above for FIG. 4A and FIG. 4B, and those aspects need not be repeated below. In particular, and in at least certain aspects, the processing conditions for embedding the additives 422 into the dry composition 426 of FIG. 4C can be viewed as largely parallel to those used when embedding the additives 412 into the dry composition 408 of FIG. 4B. The following provides further details on embodiments related to ceramics and ceramic precursors.

In some embodiments, additives are embedded into a dry composition in the form of a coating of an uncured (or not fully cured) ceramic precursor, which has been initially dried but is later swelled by an embedding fluid. This is followed by drying of the embedding fluid, contracting a coating matrix around the additives. In some instances, the embedding fluid can include the same solvent (or another solvent having similar characteristics) as that of the ceramic precursor prior to drying, in which case the processing conditions can be viewed as largely parallel to those used when embedding additives into a wet composition. Embedding of additives is followed by the option of curing or otherwise converting the ceramic precursor to a fully condensed or restructured glass.

In some embodiments, reactive species are selected to be initially oligomeric or polymeric (e.g., as opposed to monomers like TEOS or TMOS) prior to hydrolysis and condensation. Such oligomeric or polymeric form of the reactive species can promote swelling in the presence of an embedding fluid. Examples include reactive species available under the designations of Methyl 51, Ethyl 50, Ethyl 40, and the like. In other embodiments, oligomeric or polymeric reactive species can be formed by reacting monomeric reactive species, such as via hydrolysis and condensation, to reach a desired molecular weight. The oligomeric or polymeric reactive species can be combined with monomeric reactive species, with the different species being miscible, partially miscible, or largely immiscible. Such oligomeric or polymeric reactive species also can be used according to the left-side option of FIG. 4C, namely by including such oligomeric or polymeric reactive species in a coating of a liquid ceramic precursor and embedding additives into the coating prior to drying, optionally in the presence of an embedding fluid.

In some embodiments, reactive species can include monomers with up to two reactive sites, such as silicones, silsesquioxanes, and the like. Upon reaction, such reactive species can form polymer chains with a controllable amount of cross-linking, thereby promoting swelling in the presence of an embedding fluid and facilitating embedding of additives. For example, the reactive species can include Si(OR)₂R′₂, such as Si(OCH₂CH₃)₂(CH₃)₂, which typically does not crosslink below about 400° C., can swell with an embedding fluid due to its polymeric nature, and can be subsequently cross-linked into a glass by heating to above 400° C. Such polymeric reactive species also can be used according to the left-side option of FIG. 4C, namely by including such polymeric reactive species in a coating of a liquid ceramic precursor and embedding additives into the coating prior to drying, optionally in the presence of an embedding fluid.

### EXAMPLES

The following examples describe specific aspects of some embodiments of the invention to illustrate and provide a description for those of ordinary skill in the art. The examples should not be construed as limiting the invention, as the examples merely provide specific methodology useful in understanding and practicing some embodiments of the invention.

### Example 1

### Formation of Transparent Conducting Electrode Via One-Step Embedding

Silver nanowires (diameter=90 nm and length=60 μm) are vortexed for 5 sec and dispersed in a solution of isopropanol (50 vol. %) and 2,2,2-trifluoroethanol (50 vol. %) (Alfa Aesar 99%+) at a concentration of 5 mg/ml. The solution containing the silver nanowires is cup coated onto a flat sheet of a transparent acrylic (polymethyl methacrylate, Sign Mart, Inc.) with a blade separated by 1 mil from the acrylic sheet and drawn at a speed of 3 inches/sec under 20° C. and 23% humidity. 0.5 ml of the nanowire-containing solution sufficiently covered half of a square foot of the acrylic sheet. This formulation and procedure yielded silver nanowires effectively solvent-embedded such that the nanowires are partially exposed at the surface of the acrylic sheet, exhibiting a transmittance T of 86.6% including the acrylic sheet and a sheet resistance R of 29±6 Ω/sq (stdev) as measured by a Jenway UV-vis spectrophotometer and a SP4-Keithley four-point probing system. The nanowire embedded acrylic sheet is scotch tape adhesion tested and exhibited no observable change in transmittance, sheet resistance, and other properties, demonstrating the durability of the embedded nanowires.

### Example 2

### Formation of Transparent Conducting Electrode Via Two-Step Embedding

Silver nanowires (diameter=90 nm and length=60 μm) are dispersed in isopropanol at a concentration of 2.5 mg/ml and then applied onto a surface of a transparent acrylic (polymethyl methacrylate, Sign Mart, Inc.) with a Meyer rod (Gard Co.) with a wire separation distance of 20 mils and drawn at a speed of 2.5 inches/sec. After coating, the resulting nanowire network and the acrylic substrate are exposed to a vapor of tetrahydrofuran (J. T. Baker 99.5% stabilized with BHT) for 40 mins by inverting the nanowire network to be face down on a circular cross section container of diameter 100 mm×20 mm containing 40 ml of tetrahydrofuran at the bottom. This formulation and procedure yielded silver nanowires effectively solvent-embedded into the surface of the acrylic substrate, exhibiting a transmittance T of 74.3% including the acrylic substrate and a sheet resistance R of 31±2 Ω/sq (stdev). The nanowire embedded acrylic substrate is scotch tape adhesion tested and exhibited no observable change in transmittance, sheet resistance, and other properties, demonstrating the durability of the embedded nanowires.

### Example 3

### Formation of Transparent Conducting Electrode Via Two-Step Embedding

Silver nanowires (diameter=90 nm and length=60 μm) are dispersed in methanol (Sigma Aldrich 99%+) at a concentration of 1 mg/ml and then applied onto a polycarbonate substrate (Makrolon®) via a Iwata LPH400 HVLP spray gun operating at 20 psi inlet pressure 9 inches separated from the substrate under 20° C. and 30% humidity. The evaporation rate of the methanol, along with the spray gun settings that dispense an extremely fine atomized conical pattern from a nozzle, yielded a spray that substantially vaporizes before the methanol ejecting from the nozzle reaches the substrate 9 inches away. The methanol served to effectively suspend the nanowires, and the methanol and the atomizing air pressure act as a propellant to convey the nanowires towards the substrate. However, the methanol substantially vaporizes and does not wet the substrate surface, thereby avoiding or reducing uneven wetting of the substrate surface that can cause migration, agglomeration, coffee-stain ring effects, Bénard cells, and other spatial non-uniformities of a deposited nanowire network. The resulting dry nanowire network adhered to the substrate is then exposed to a vapor of acetone (Sigma Aldrich >99.9%) for 10 mins to permit solvent-assisted embedding of the nanowire network into the substrate by inverting the nanowire network to be face down on a circular cross section container of diameter 100 mm×20 mm containing 40 ml of acetone at the bottom. This formulation and procedure yielded silver nanowires effectively solvent-embedded into the surface of the substrate, exhibiting a transmittance T of 74.4% including the polycarbonate substrate and a sheet resistance R of 23 Ω/sq. The nanowire embedded polycarbonate substrate is scotch tape adhesion tested and exhibited no observable change in transmittance, sheet resistance, and other properties, demonstrating the durability of the embedded nanowires.

### Example 4

### Formation of Embedded Substrate Via One-Step Embedding

A powder of silver-silica (5 micron) is suspended in a solution of methyl acetate (60 vol. %)/ethyl acetate (20 vol. %)/cyclohexanone (20 vol. %) at a concentration of 6.4 mg/ml, agitated, and then sprayed onto a substrate of transparent polycarbonate using an Iwata LPH101 HVLP spray gun operating at 20 psi inlet pressure, 1.3 mm needle size, and 8 inches separated from the substrate under 20° C. and 40% humidity. After the nanowire-containing solution has been exposed to the substrate for several seconds, the solvent system volatilizes off under ambient room temperature conditions and durably embeds particles into the softened polycarbonate surface.

### Example 5

### Formation of Transparent Conducting Electrode on Glass

To a 40 mL scintillation vial was added 18.5 mL of dry 200 proof ethanol (CAS#67-17-5), 0.075 mL of 1M hydrochloric acid in deionized (“DI”) water (18×10⁶Ω), and 0.92 mL of additional DI water. This mixture was stirred until homogeneous. To this mixture was added 5.6 mL of tetraethoxysilane (TEOS, CAS#78-10-4, a.k.a. tetraorthosilicate, Si(OC₂H₅)₄) while stirring rapidly. Stirring continued until the resulting solution was homogeneous (about 15 minutes), and the solution was stored at 60° C. for 2 days in order to partially polymerize via condensation.

A glass substrate was cleaned with a 2 vol. % Micro90 solution via mechanical agitation using a clean sponge followed by two DI water rinse baths and flowing DI water. The glass substrate was kept in a DI water bath (no more than 3 hours) to await the next stage. The glass substrate was removed from the water bath, transferred into an isopropanol (IPA, a.k.a. 2-propanol) bath, followed by a rinse with running IPA (squirt bottle), and finished with an air knife dry step using an HVLP spray gun. Just prior to deposition of the TEOS solution, the glass substrate was put into a UVO chamber (UVOCS Corp. T10×10) for 20 minutes for surface preparation.

The TEOS solution was deposited onto the glass substrate by spin casting at 1,250 revolutions per minute for 60 sec. After curing for 10 minutes at room temperature in a chamber containing 1 drop of 1M hydrochloric acid, 0.3 mL of 2.5 mg/mL silver nanowires in 3:1::Methanol:IPA were sprayed onto the surface using an Iwata LPH400 HVLP spray gun with a 1.3 mm needle and operating at 45 psi air pressure at the source.

### Example 6

### Formation of Transparent Conducting Electrode on TEOS glass

A glass substrate was cleaned with a 2 vol. % Micro90 solution via mechanical agitation using a clean sponge followed by two DI water rinse baths and flowing DI water. The glass substrate was kept in a DI water bath (no more than 3 hours) to await the next stage. The glass substrate was removed from the water bath, transferred into an isopropanol (IPA, a.k.a. 2-propanol) bath, followed by a rinse with running IPA (squirt bottle), and finished with an air knife dry step using an HVLP spray gun. Just prior to deposition of the TEOS solution, the glass substrate was put into a UVO chamber (UVOCS Corp. T10×10) for 20 minutes for surface preparation.

A spin-on glass (Filmtronics Inc., SOG 20B) was used as received and deposited onto the glass substrate by spin casting at 2,000 revolutions per minute for 5 sec, resulting in a tacky film of about 300 nm thickness. After curing for 20 minutes at 75° C. following the deposition of the spin-on-glass, 5 mL of 1.0 mg/mL silver nanowires in 9:1::Methanol:IPA were sprayed onto the surface from 10 inches away using an Iwata HPTH air brush operating at 20 psi air pressure at the source and a flow set by turning a needle adjustment knob 180° counter-clockwise. This formulation and procedure yielded a transmittance T of 79.1% including the glass substrate and a sheet resistance R of 3,000 Ω/sq.

### Example 7

### Formation of Transparent Conducting Electrode

A glass substrate was cleaned with a 2 vol. % Micro90 solution via mechanical agitation using a clean sponge followed by two DI water rinse baths and flowing DI water. The glass substrate was kept in a DI water bath (no more than 3 hours) to await the next stage. The glass substrate was removed from the water bath, transferred into an isopropanol (IPA, a.k.a. 2-propanol) bath, followed by a rinse with running IPA (squirt bottle), and finished with an air knife dry step using an HVLP spray gun. Just prior to deposition of the TEOS solution, the glass substrate was put into a UVO chamber (UVOCS Corp. T10×10) for 20 minutes for surface preparation.

A spin-on glass (Filmtronics Inc., SOG 20B) was used as received and deposited onto the glass substrate by spin casting at 2,000 revolutions per minute for 30 sec. Immediately after beginning spin casting of the spin-on-glass (while still spinning), 0.5 mL of 5.0 mg/mL silver nanowires in 1:1::Methanol:IPA were sprayed onto the surface from 10 inches away using an Iwata HP-C5 air brush operating at 40 psi air pressure at the source. The coated substrate was cured at 75° C. for 20 minutes following spin-on-glass and nanowire deposition. This formulation and procedure yielded a transmittance T of 57.1% including the glass substrate and a sheet resistance R of 39 Ω/sq.

### Example 8

### Formation and Characterization of Transparent Conducting Electrodes

Transparent conducting electrodes were formed to feature embedded, planar region of silver nanowire networks in polycarbonate. Four conducting pads were deposited for four-point probe electrical conductivity measurements, which showed a sheet resistance R of 3.2 Ω/sq for at least one sample. This resistance value is an improvement over typical sheet resistance values of transparent conducting electrodes used in silicon solar cells (30 to 100 Ω/sq), and over typical sheet resistance values of transparent conducting electrodes used in displays (100-350 Ω/sq). Transmittance values were determined using UV-vis photo-spectrometry, and sheet resistance values were determined using the four-point probe method and cross checked with the Van-der Pauw method and the two-point probe method. With these values, DC-to-optical conductivity ratios were derived. Nanowire networks surface-embedded in substrates exhibited higher DC-to-optical conductivity ratios than their non-embedded (superficially deposited) counterparts. The nanowire networks remain intact upon embedding, with little or no inhibition of electrical percolation. At the same time, the embedded nature of the nanowire networks yielded durable transparent conducting electrode with sheet resistance values substantially unaltered over multiple scotch-tape durability stressing tests and physical abrasion.

### Example 9

### Characterization of Transparent Conducting Electrodes

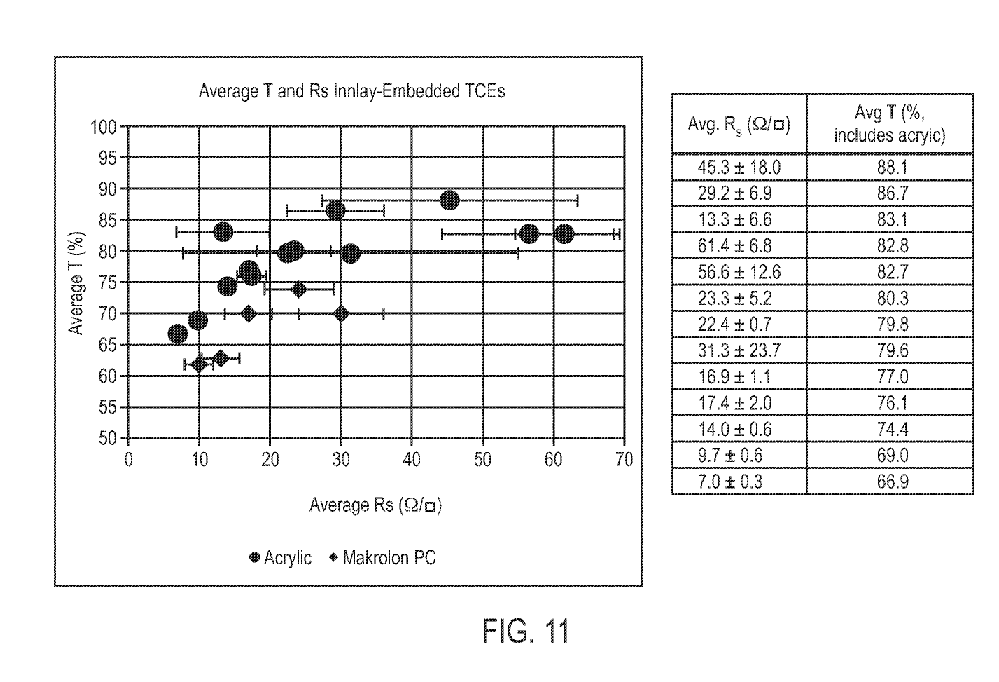

FIG. 11 illustrates a tradeoff curve of transmittance and corresponding sheet resistance (at constant DC-to-optical conductivity ratio) of silver nanowire networks surface-embedded into polycarbonate films and acrylic, where the horizontal lines denote standard deviations of the sheet resistance over a given surface.

### Example 10

### Characterization of Transparent Conducting Electrodes

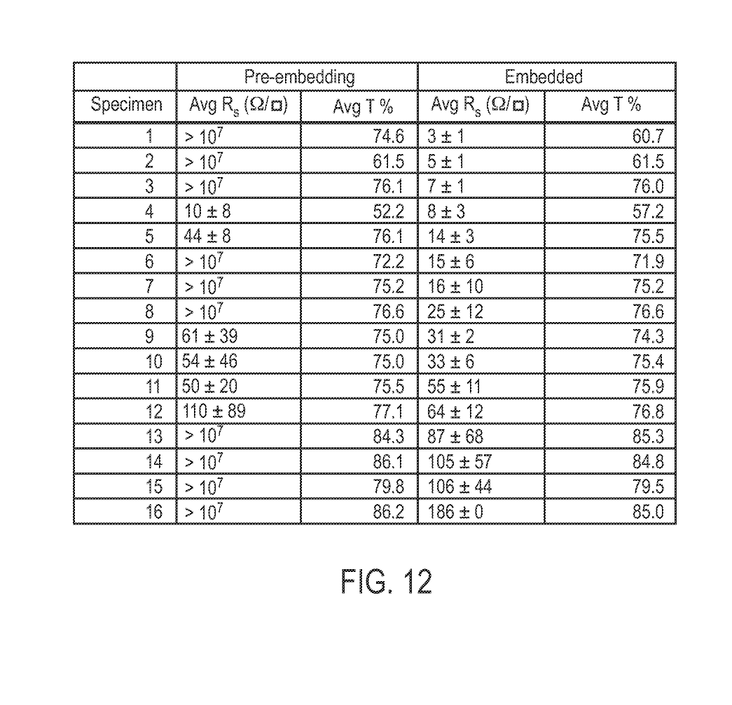

FIG. 12 is a table of transparency and sheet resistance data collected on samples manufactured via a two-step deposition and embedding method, comparing data directly after deposition and after surface-embedding. Coupons of acrylic aircraft transparencies were made to compare the differences between acrylic with superficially deposited nanowires and acrylic with surface-embedded nanowires. Most coupons with superficially deposited nanowires showed undetectably high sheet resistance values exceeding the 10 MΩ limit of the four-point probe tool used (Keithley Digital Multimeter) before and after a simple durability stress test (Scotch tape method), whereas surface-embedded coupons showed low sheet resistance that was largely unaltered by the stress test.

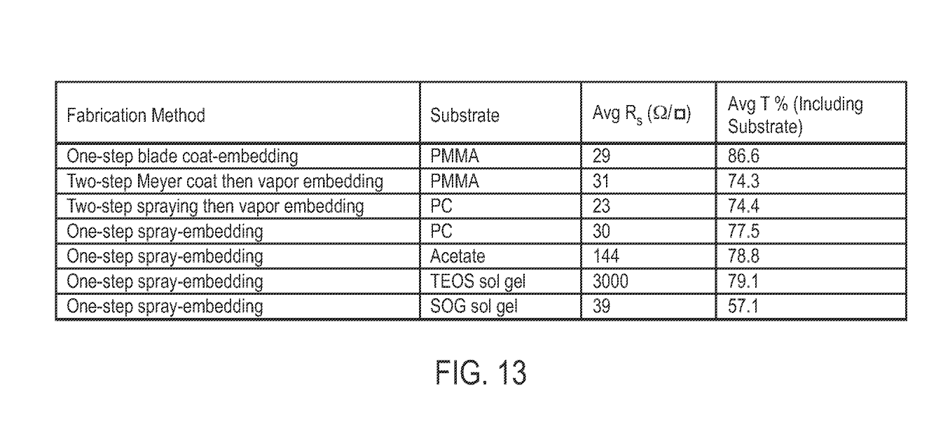

FIG. 13 is a table summarizing typical, average sheet resistance and transparency data for different methods of fabricating TCEs with surface-embedded additives.

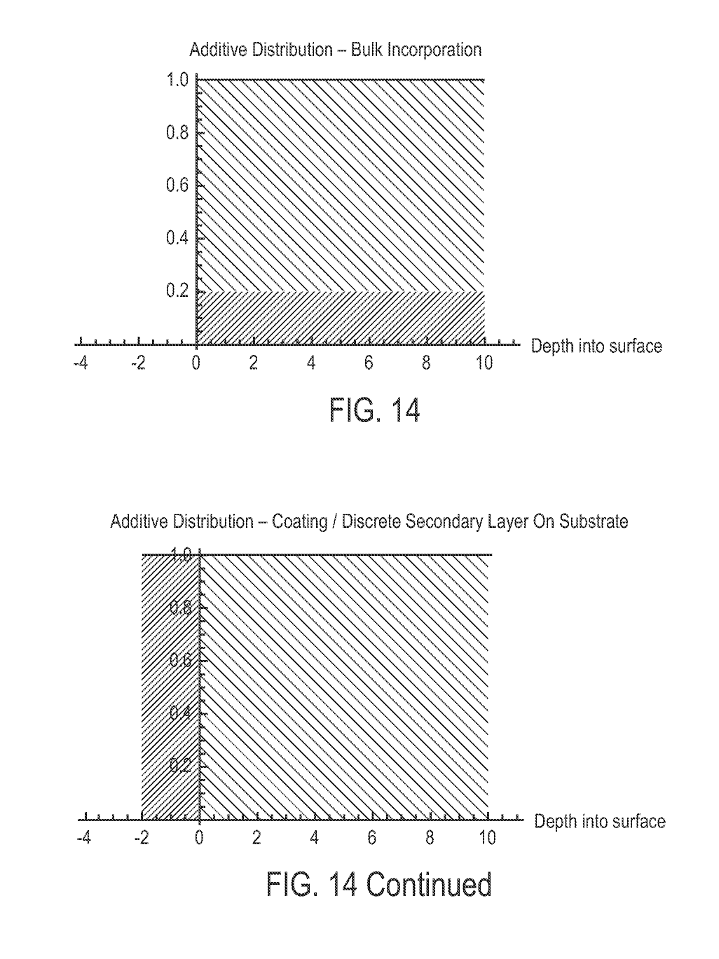

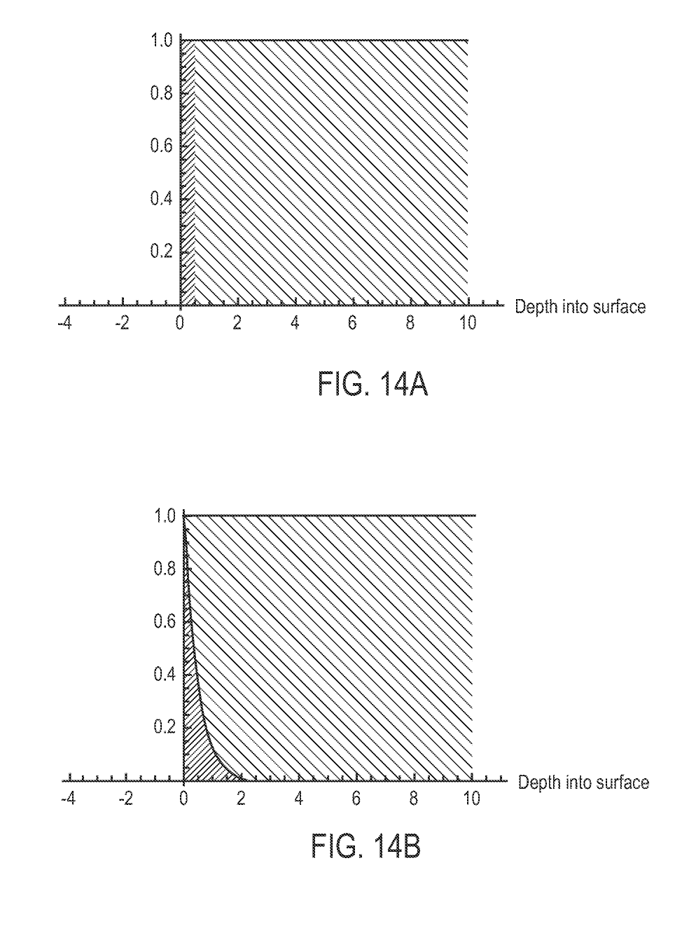

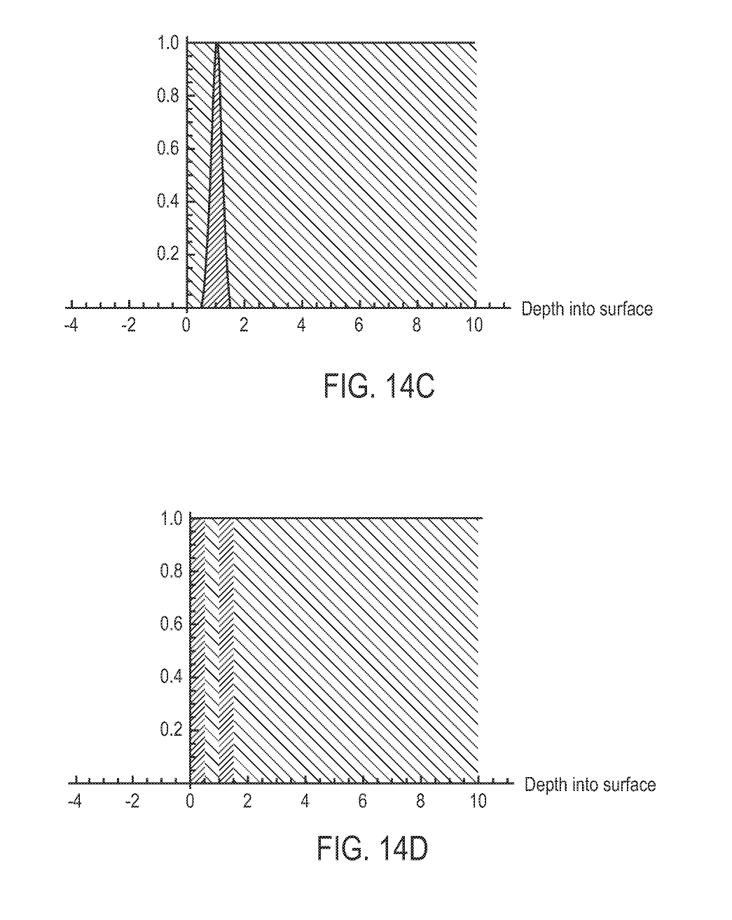

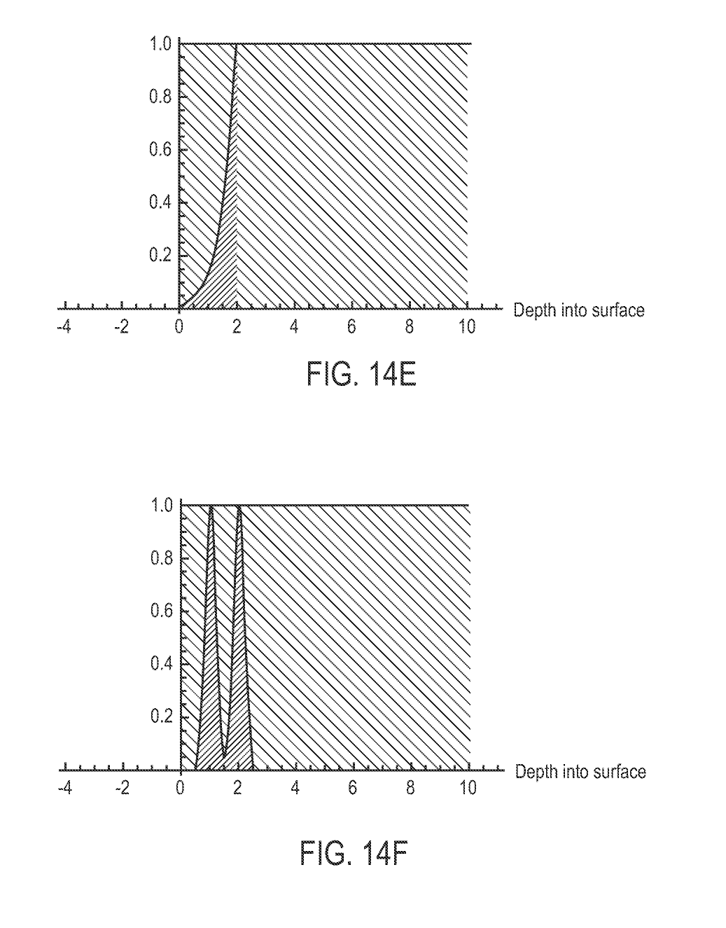

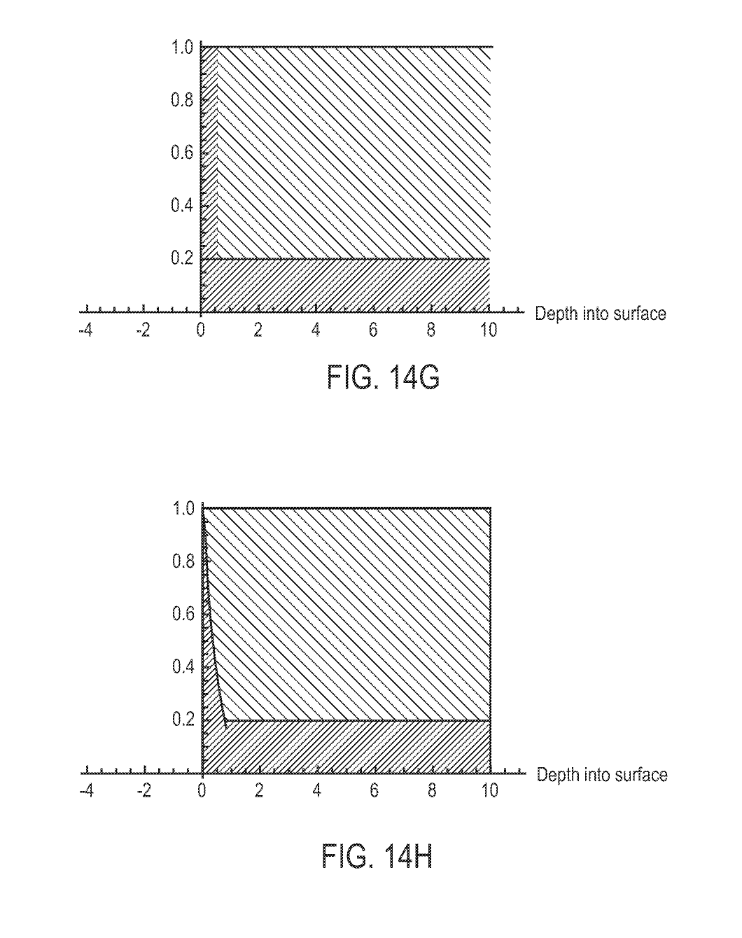

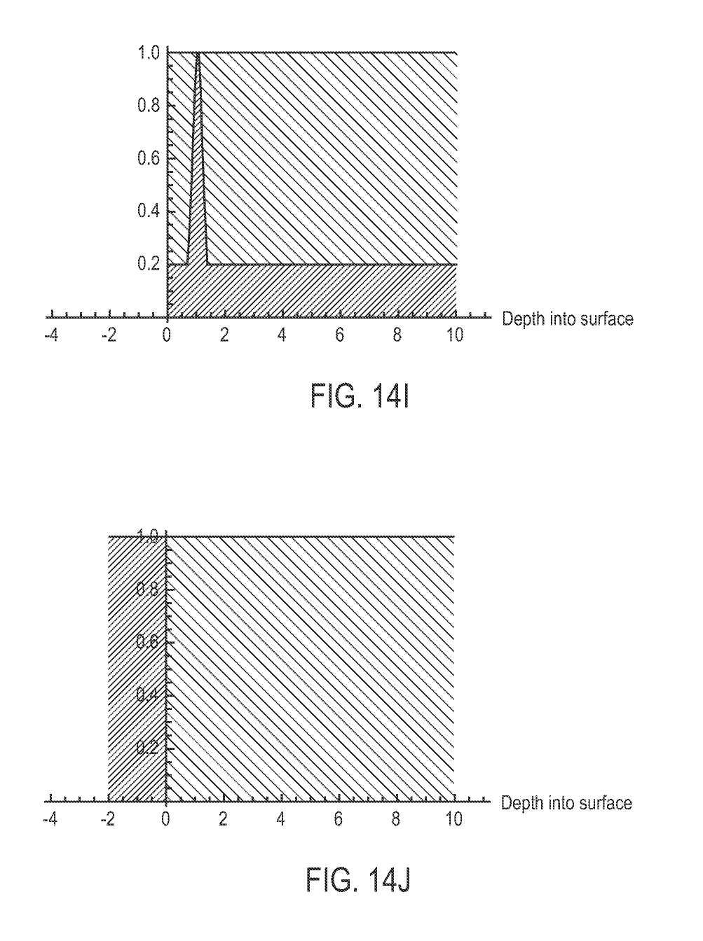

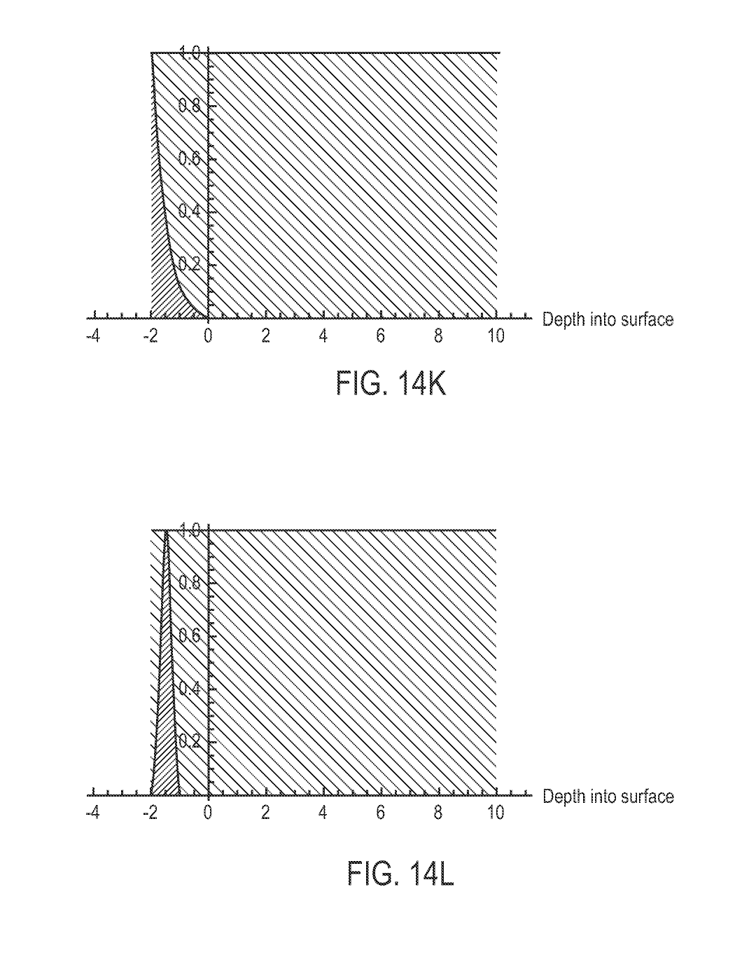

FIG. 14 depicts various configurations of additive concentrations relative to an embedding surface of a host material, where the finite additive concentrations denote the embedding regions. For all of the plots in FIG. 14, the host material is confined between the x-axis values of 0 and 10, denoted with the light color. If a coating is present, then it is deposited on top of the host material, and is located between x=−2 and x=0, denoted in a light gray color. The x-axes denote the depth/thickness of the host material from the embedding surface. The first plot is of a substrate that has been bulk incorporated or compounded with additives mixed throughout the bulk of the entire substrate. Its additive concentration is depicted as a uniform distribution with the dark gray shade held at y=0.2 concentration. Surface-embedded additives can be localized in a discrete step or delta function as a function of thickness or depth from the embedding surface of the host material, as depicted in FIG. 14(a). Alternatively, the additives can be largely localized at the embedding surface but having a concentration tailing off the deeper into the embedding surface as in FIG. 14(b) or the closer to the embedding surface as in FIG. 14(e). Additives can be surface-embedded fully beneath the embedding surface in the fashion of FIG. 14(c), where there is a maximum concentration of additives at a discrete depth followed by a tailing off of additive concentration from that discrete depth below the embedding surface in both directions. Multiple depths of additive embedding can be achieved by adjusting parameters to tune the depth of embedding, and multiple operations can be performed onto the substrate to permit this multiple layered embedding geometry as captured in FIG. 14(d) and FIG. 14(f). Similar geometries can be achieved by surface-embedding via the aforementioned approaches but on (or in) a substrate that has already been bulk incorporated, as in FIGS. 14(g), (h), and (i). Similar geometries can be achieved by surface-embedding not only onto a substrate material but also into a coating layer of a coated material, as those depicted in FIGS. 14(j), (k), and (l).

### Example 11

### Characterization of Transparent Conducting Electrodes

Silver nanowires (mean length=7 μm, mean diameter=70 nm) were embedded into transparent polycarbonate to a depth below the surface, yielding transmittance values at or above 80% and sheet resistance values at or below 100 Ω/sq. Sheet resistance values below 10 Ω/sq (e.g., as low as 3 Ω/sq) can be attained with further optimization. A scanning electron microscope image with a focused ion beam was used to reveal a cross section with a monolithic host material (e.g., in the absence of a coating or interfaces) and a planar region of embedded silver nanowires below the surface.

### Example 12

### Characterization of Transparent Conducting Electrodes

Silver nanowires (mean length=7 μm, mean diameter=70 nm) were embedded into transparent polycarbonate to a depth less than 100% of the diameter of the nanowires, yielding transmittance values of about 90% and sheet resistance values of about 100 Ω/sq. Sheet resistance values below 10 Ω/sq (e.g., as low as 3 Ω/sq) can be attained with further optimization.

### Example 13

### Formation of Transparent Conducting Electrode

Silver nanowires (mean length=7 μm, mean diameter=70 nm) and ITO nanoparticles (diameter <100 nm) were embedded into transparent polycarbonate to a depth less than 100% of the diameter of the nanowires and less than 100% of the diameter of the nanoparticles.

While the invention has been described with reference to the specific embodiments thereof, it should be understood by those skilled in the art that various changes may be made and equivalents may be substituted without departing from the true spirit and scope of the invention as defined by the appended claims. In addition, many modifications may be made to adapt a particular situation, material, composition of matter, method, or process to the objective, spirit and scope of the invention. All such modifications are intended to be within the scope of the claims appended hereto. In particular, while the methods disclosed herein have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations are not limitations of the invention.

What is claimed is:

1. A manufacturing method to form a transparent conductive electrode, comprising:
providing a wet composition on a substrate;
applying metallic nanowires to the wet composition to at least partially embed the metallic nanowires into the wet composition; and
converting the wet composition into a coating with the metallic nanowires at least partially embedded into the coating, wherein converting the wet composition includes at least one of curing, cross-linking, and polymerizing the wet composition.

2. The manufacturing method of claim 1, wherein the wet composition includes a ceramic precursor, and converting the wet composition includes curing the ceramic precursor to form a ceramic.

3. The manufacturing method of claim 1, wherein the wet composition includes a ceramic precursor that includes a solvent and a set of reactive species.

4. The manufacturing method of claim 3, wherein providing the wet composition includes at least partially reacting the reactive species prior to applying the metallic nanowires to the wet composition.

5. The manufacturing method of claim 1, wherein providing the wet composition includes applying the wet composition on the substrate as a spin-on glass.

6. The manufacturing method of claim 1, wherein the wet composition includes at least one of a silane, a titanium analogue of a silane, a cerium analogue of a silane, a magnesium analogue of a silane, a germanium analogue of a silane, a siloxane, a titanium analogue of a siloxane, a cerium analogue of a siloxane, a magnesium analogue of a siloxane, and a germanium analogue of a siloxane.

7. The manufacturing method of claim 1, wherein the wet composition includes a ceramic precursor that includes at least one of a Si—O—Si linkage, a Si—C linkage, and a Si—C—Si linkage.

8. The manufacturing method of claim 1, wherein converting the wet composition includes forming the coating by a sol-gel process.

9. The manufacturing method of claim 1, wherein the wet composition includes a cross-linkable precursor, and converting the wet composition includes cross-linking the precursor to form the coating.

10. The manufacturing method of claim 1, wherein the wet composition includes a precursor that includes at least one of a monomer and an oligomer, and converting the wet composition includes polymerizing the precursor to form the coating.

11. The manufacturing method of claim 1, wherein the metallic nanowires include silver nanowires.

12. The manufacturing method of claim 1, wherein applying the metallic nanowires includes propelling the metallic nanowires towards the wet composition.

13. The manufacturing method of claim 1, wherein applying the metallic nanowires includes applying an embedding fluid to the wet composition to facilitate embedding of the metallic nanowires into the wet composition.

14. A manufacturing method to form a transparent conductive electrode, comprising:
providing a substrate;
providing metallic nanowires and an embedding fluid; and
using the embedding fluid, embedding the metallic nanowires into a surface of the substrate, such that the metallic nanowires are localized within a depth from the surface that is no greater than 40% of an overall thickness of the substrate.

15. The manufacturing method of claim 14, wherein the depth of embedding of the metallic nanowires is no greater than 30% of the overall thickness of the substrate.

16. The manufacturing method of claim 14, wherein at least one of the metallic nanowires has a diameter in the range of 1 nm to 100 nm, and the depth of embedding of the metallic nanowires is at least 10% of the diameter.

17. The manufacturing method of claim 14, wherein at least one of the metallic nanowires is fully embedded below the surface of the substrate.

18. The manufacturing method of claim 14, wherein at least one of the metallic nanowires includes a portion exposed above the surface of the substrate.

19. The manufacturing method of claim 14, wherein embedding the metallic nanowires includes applying the embedding fluid to the substrate, such that the embedding fluid softens the substrate to embed the metallic nanowires into the substrate.

20. The manufacturing method of claim 14, wherein providing the metallic nanowires and the embedding fluid includes providing a dispersion of the metallic nanowires in the embedding fluid, and embedding the metallic nanowires includes applying the dispersion to the substrate.

21. The manufacturing method of claim 14, wherein the substrate includes a polymer, and the embedding fluid includes a solvent for the polymer.

22. The manufacturing method of claim 21, wherein the embedding fluid includes at least two different solvents.

23. The manufacturing method of claim 14, further comprising applying a coating overlying the metallic nanowires.

24. The manufacturing method of claim 23, wherein the coating includes an electrically conductive material.

25. The manufacturing method of claim 14, further comprising sintering the metallic nanowires to fuse together at least a subset of the metallic nanowires.

26. A transparent conductive electrode comprising:
a substrate;
a coating disposed on the substrate, wherein the coating has an embedding surface, and the embedding surface faces away from the substrate; and
metallic nanowires at least partially embedded into the embedding surface of the coating and localized within an embedding region adjacent to the embedding surface, wherein a thickness of the embedding region is less than an overall thickness of the coating, and at least one of the metallic nanowires includes a portion exposed above the embedding surface,
wherein the transparent conductive electrode has a transmittance of at least 85% and a sheet resistance no greater than 200 Ω/sq.

27. The transparent conductive electrode of claim 26, wherein the thickness of the embedding region is no greater than 30% of the overall thickness of the coating, and a remainder of the coating is devoid of any metallic nanowire.

28. The transparent conductive electrode of claim 26, wherein the at least one of the metallic nanowires includes the portion that extends out from the embedding surface to an extent from 1 nm to 50 nm.

29. The transparent conductive electrode of claim 26, wherein at least another one of the metallic nanowires is fully embedded below the embedding surface.

30. The transparent conductive electrode of claim 26, wherein the metallic nanowires include metallic nanowires that are fused together.
